(19) United States
(12) Patent Application Publication
(10) Pub. No.: US 2026/0114166 A1
(43) Pub. Date: Apr. 23, 2026

(54) DISPLAY DEVICE AND ELECTRONIC DEVICE INCLUDING THEREOF

(71) Applicant: SAMSUNG DISPLAY CO., LTD., YONGIN-SI (KR)

(72) Inventors: Young Chan KIM, Yongin-si (KR); Jae Ho YOU, Yongin-si (KR); Beom Shik KIM, Yongin-si (KR); Eun Kyoung NAM, Yongin-si (KR); Hyun Jin CHO, Yongin-si (KR)

(21) Appl. No.: 19/359,877

(22) Filed: Oct. 16, 2025

(30) Foreign Application Priority Data
Oct. 21, 2024 (KR) 10-2024-0143780

(51) Int. Cl. H10K 59/80; H10K 59/122; H10K 59/40; H10K 102/00

(52) U.S. Cl. CPC H10K 59/879; H10K 59/122; H10K 59/40; H10K 59/873; H10K 2102/331

(57) ABSTRACT

A display device and an electronic device including the same are provided, and the display device includes a substrate, a plurality of light-emitting areas comprising a plurality of light-emitting elements is arranged on the substrate, a pixel-defining layer defining the plurality of light-emitting areas, an encapsulation layer disposed on the plurality of light-emitting elements and the pixel-defining layer, and a metalens layer disposed on the encapsulation layer and comprising a plurality of metalenses. The plurality of metalenses overlaps with some of the plurality of light-emitting areas in a thickness direction of the substrate.

This application claims priority under 35 U.S.C. § 119 to Korean Patent Application No. 10-2024-0143780, filed on Oct. 21, 2024 in the Korean Intellectual Property Office, the disclosure of which is incorporated by reference in its entirety herein.

### 1. TECHNICAL FIELD

The present disclosure relates to a display device and an electronic device including thereof.

### 2. DISCUSSION OF RELATED ART

Along with the advancement of communication technology and media, display devices are being applied to an increasing variety of electronic devices to display images in many types of places and environments. For example, a variety of types of display devices such as liquid-crystal display (LCD) devices and organic light-emitting display (OLED) devices are widely used.

A three-dimensional (3D) image display device has recently been developed to provide divided images of the display device in the space in front of the display device using a lens array. A 3D image display device separately displays a left-eye image and a right-eye image to provide the viewer with a 3D visual experiences using binocular parallax.

### SUMMARY

Aspects of the present disclosure provide a display device and an electronic device including thereof that can display 3D images without a liquid-crystal lens requiring application of voltage and can switch between a 2D mode and a 3D mode.

According to an embodiment of the present disclosure, a display device includes a substrate. A plurality of light-emitting areas comprising a plurality of light-emitting elements is arranged on the substrate. A pixel-defining layer defines the plurality of light-emitting areas. An encapsulation layer is disposed on the plurality of light-emitting elements and the pixel-defining layer. A metalens layer is disposed on the encapsulation layer and comprises a plurality of metalenses. The plurality of metalenses overlaps with some of the plurality of light-emitting areas in a thickness direction of the substrate.

In an embodiment, the plurality of metalenses may not overlap with some others of the light-emitting areas in the thickness direction of the substrate.

In an embodiment, the plurality of light-emitting areas may include a plurality of first light-emitting areas emitting light of a first color, a plurality of second light-emitting areas emitting light of a second color, and a plurality of third light-emitting areas emitting light of a third color. The first to third colors are different from each other.

In an embodiment, the plurality of metalenses may include a first metalens overlapping with one of the plurality of first light-emitting areas in the thickness direction of the substrate and refracting light of the first color, a second metalens overlapping with one of the plurality of second light-emitting areas in the thickness direction of the substrate and refracting light of the second color, and a third metalens overlapping with one of the plurality of third light-emitting areas in the thickness direction of the substrate and refracting light of the third color.

In an embodiment, the first metalens may include first nanostructures having a first spacing, a first width and a first height, and the second metalens may include second nanostructures having a second spacing, a second width and a second height. The first nanostructures may have a different nanostructure than the second nanostructures.

In an embodiment, the third metalens may include third nanostructures having a third gap, a third width and a third height. The third nanostructures may have a different nanostructure than the first nanostructures and the second nanostructures.

In an embodiment, the plurality of metalenses may include a first metalens, a second metalens and a third metalens overlapping in the thickness direction of the substrate with one of the plurality of first light-emitting areas, one of the plurality of second light-emitting areas and one of the plurality of third light-emitting areas. The first metalens, the second metalens and the third metalens may overlap one another in the thickness direction of the substrate.

In an embodiment, the first metalens may include fourth nanostructures having a fourth spacing, a fourth width and a fourth height, the second metalens may include fifth nanostructures having a fifth spacing, a fifth width and a fifth height, the third metalens may include sixth nanostructures having a sixth spacing, a sixth width and a sixth height. The fourth to sixth nanostructures may overlap one another in the thickness direction of the substrate.

In an embodiment, the fourth nanostructures, the fifth nanostructures and the sixth nanostructures may have different nanostructures from one another.

In an embodiment, each of the plurality of first light-emitting areas may include a plurality of first subsidiary light-emitting areas, each of the plurality of second light-emitting areas may include a plurality of second subsidiary light-emitting areas. The plurality of first subsidiary light-emitting areas may be arranged adjacent to each other in a first direction parallel to an upper surface of the substrate, the plurality of second subsidiary light-emitting areas may be arranged adjacent to each other in the first direction. The plurality of first subsidiary light-emitting areas and the plurality of second subsidiary light-emitting areas are arranged alternately in a second direction perpendicular to the first direction and parallel to the upper surface of the substrate.

In an embodiment, the plurality of metalenses may include a first metalens overlapping with one of the plurality of first subsidiary light-emitting areas in the thickness direction of the substrate, and a second metalens overlapping with one of the plurality of second subsidiary light-emitting areas in the thickness direction of the substrate.

In an embodiment, at least one first subsidiary light-emitting area or second subsidiary light-emitting area may be disposed between the first metalens and the second metalens in the first direction.

In an embodiment, the first metalens and the second metalens may be adjacent to each other in the second direction.

In an embodiment, a distance between the first metalens and the second metalens adjacent to each other in the first direction may be greater than a distance between the first metalens and the second metalens adjacent to each other in the second direction.

In an embodiment, the display device may further include a color filter layer including color filters and a black matrix disposed on the encapsulation layer. The plurality of metalenses may overlap with the color filters in the thickness direction of the substrate.

In an embodiment, edges of the plurality of metalenses may overlap with the pixel-defining layer in the thickness direction of the substrate.

In an embodiment, the display device may further include a touch sensing layer disposed on the encapsulation layer and including touch electrodes. Edges of the plurality of metalenses may overlap with edges of the touch electrodes in the thickness direction of the substrate.

In an embodiment, the display device may further include a touch sensing layer disposed on the encapsulation layer and including touch electrodes. The plurality of metalenses may not overlap with the touch electrodes in the thickness direction of the substrate.

In an embodiment, the display device may further include a polarizing member disposed on the encapsulation layer.

In an embodiment, the polarizing member may be disposed directly on a surface of the metalens layer.

In an embodiment, the polarizing member may be spaced apart from the metalens layer and does not directly contact the metalens layer.

In an embodiment, the display device may further include a touch sensing layer disposed on the encapsulation layer. The polarizing member may be disposed between the touch sensing layer and the metalens layer in the thickness direction of the substrate.

In an embodiment, the display device may further include a touch sensing layer disposed on the encapsulation layer. The metalens layer may be disposed between the touch sensing layer and the polarizing member in the thickness direction of the substrate.

The display device may further include a touch sensing layer disposed between the metalens layer and the polarizing member.

According to an embodiment of the present disclosure, an electronic device includes a display device. The display device includes a substrate. A plurality of light-emitting areas comprising a plurality of light-emitting elements is arranged on the substrate. A pixel-defining layer defines the plurality of light-emitting areas. An encapsulation layer is disposed on the plurality of light-emitting elements and the pixel-defining layer. A metalens layer is disposed on the encapsulation layer and including a plurality of metalenses. The plurality of metalenses may overlap with some of the plurality of light-emitting areas in a thickness direction of the substrate.

These and other aspects, embodiments and advantages of the present disclosure will become immediately apparent to those of ordinary skill in the art upon review of the Detailed Description and Claims.

Previously, an existing 3D display device switches between a 2D mode and a 3D mode by applying power to a liquid-crystal lens. However, there was a problem with the sensitivity of the touch panel being decreased. In view of the above, according to some embodiments of the present disclosure, by using metalenses that do not require application of voltage instead of a liquid-crystal lens previously used to display 3D images, it is possible to address the problem of the decrease sensitivity of the touch sensing layer.

Previously, an existing 3D display device requires application of voltage to switch between a 2D mode and a 3D mode. Therefore, the touch sensing layer has to be disposed at the top. In contrast, according to some embodiments of the present disclosure, by using metalenses that do not require application of voltage instead of a liquid-crystal lens previously used to display 3D images, the touch sensing layer may not be disposed at the top and may be disposed between an emissive layer and a window member, which can reduce the difficulty of the fabrication process.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail non-limiting embodiments thereof with reference to the attached drawings:

FIG. 1 is a perspective view of a display device according to an embodiment of the present disclosure.

FIG. 2 is a view showing a layout of area A of FIG. 1 according to an embodiment of the present disclosure.

FIG. 3 is a cross-sectional view of the display device, taken along line I-I′ of FIG. 2, according to an embodiment of the present disclosure.

FIG. 4 is a cross-sectional view of the display device, taken along line M-M′ of FIG. 2, according to an embodiment of the present disclosure.

FIG. 5 is a cross-sectional view of the display device, taken along line N-N′ of FIG. 2, according to an embodiment of the present disclosure.

FIG. 6 is a cross-sectional view of the display device, taken along line I-I′ of FIG. 2, according to an embodiment of the present disclosure.

FIG. 7 is a cross-sectional view of the display device, taken along line I-I′ of FIG. 2, according to an embodiment of the present disclosure.

FIG. 8 is a cross-sectional view of the display device, taken along line I-I′ of FIG. 2, according to an embodiment of the present disclosure.

FIG. 9 is a view showing a layout of area A of FIG. 1 according to an embodiment of the present disclosure.

FIG. 10 is a cross-sectional view of the display device, taken along line O-O′ of FIG. 9, according to an embodiment of the present disclosure.

FIG. 11 is a cross-sectional view of the display device, taken along line J-J′ of FIG. 9, according to an embodiment of the present disclosure.

FIG. 12 is a cross-sectional view of the display device, taken along line J-J′ of FIG. 9, according to an embodiment of the present disclosure.

FIG. 13 is a cross-sectional view of the display device, taken along line J-J′ of FIG. 9, according to an embodiment of the present disclosure.

FIG. 14 is a cross-sectional view of the display device, taken along line J-J′ of FIG. 9, according to an embodiment of the present disclosure.

FIG. 15 is a perspective view of a display device according to an embodiment of the present disclosure.

FIG. 16 is a side view of the display device of FIG. 15 according to an embodiment of the present disclosure.

FIG. 17 is a layout view specifically showing the touch sensing layer of FIG. 16 according to an embodiment of the present disclosure.

FIG. 18 is a layout diagram showing area B of FIG. 17 in detail according to an embodiment of the present disclosure.

FIG. 19 is a layout diagram showing area B of FIG. 17 in detail according to an embodiment of the present disclosure.

FIG. 20 is a cross-sectional view of the display device, taken along line K-K′ of FIG. 19, according to an embodiment of the present disclosure.

FIG. 21 is a cross-sectional view of the display device, taken along line K-K′ of FIG. 19, according to an embodiment of the present disclosure.

FIG. 22 is a cross-sectional view of the display device, taken along line K-K′ of FIG. 19, according to an embodiment of the present disclosure.

FIG. 23 is a cross-sectional view of the display device, taken along line K-K′ of FIG. 19, according to an embodiment of the present disclosure.

FIG. 24 is a cross-sectional view of the display device, taken along line K-K′ of FIG. 19, according to an embodiment of the present disclosure.

FIG. 25 is a cross-sectional view of the display device, taken along line K-K′ of FIG. 19, according to an embodiment of the present disclosure.

FIG. 26 is a cross-sectional view of the display device, taken along line K-K′ of FIG. 19, according to an embodiment of the present disclosure.

FIG. 27 is a layout diagram showing area B of FIG. 17 in detail according to an embodiment of the present disclosure.

FIG. 28 is a cross-sectional view of the display device, taken along line L-L′ of FIG. 27, according to an embodiment of the present disclosure.

FIG. 29 is a cross-sectional view of the display device, taken along line L-L′ of FIG. 27, according to an embodiment of the present disclosure.

FIG. 30 is a cross-sectional view of the display device, taken along line L-L′ of FIG. 27, according to an embodiment of the present disclosure.

FIG. 31 is a cross-sectional view of the display device, taken along line L-L′ of FIG. 27, according to an embodiment of the present disclosure.

FIG. 32 is a cross-sectional view of the display device, taken along line L-L′ of FIG. 27, according to an embodiment of the present disclosure.

FIG. 33 is a cross-sectional view of the display device, taken along line L-L′ of FIG. 27, according to an embodiment of the present disclosure.

FIG. 34 is a diagram illustrating an electronic device, according to an embodiment of the present disclosure.

### DETAILED DESCRIPTION OF EMBODIMENTS

The present disclosure will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, non-limiting embodiments will be described with reference to the attached drawings.

The present disclosure concerns a display device that includes a metalens layer overlapping only a portion of the light-emitting areas. In a 3D mode, only light output by the portion of the light-emitting areas is refracted through the metalens and propagated to a view area(s). Therefore, there is a difference in the displayed images in different view areas to provide a 3D image to the viewer.

The display device including the metalenses displays a 3D image without requiring a voltage to switch between a 2D mode and a 3D mode which provides an increased sensitivity for the touch sensing layer. The touch sensing layer may not be disposed at the top of the display device for increased efficiency of manufacture.

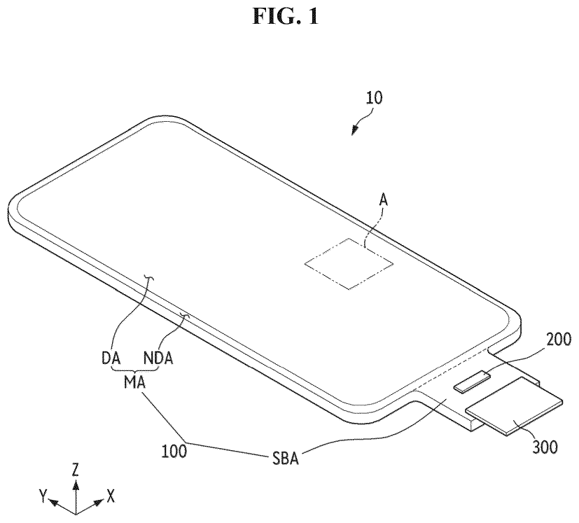

FIG. 1 is a perspective view of a display device according to some embodiments of the present disclosure.

Referring to FIG. 1, a display device 10 may display at least one still image and/or moving image. In an embodiment, the display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various electronic devices such as a television, a notebook, a monitor, a billboard and the Internet of Things (IoT) device. However, embodiments of the present disclosure are not necessarily limited thereto and the electronic device that the display device 10 may be applied to may be various different small-sized, medium-sized or large-sized electronic devices. In an embodiment, the display device 10 may be one of an organic light-emitting display device, a liquid-crystal display device, a plasma display device, a quantum dot light-emitting display device, and a micro LED display device. In the following description, an organic light-emitting display device is described as an example of the display device 10. It is, however, to be understood that embodiments of the present disclosure are not necessarily limited thereto.

The display device 10 includes a display panel 100, a display driver circuit 200 and a circuit board 300.

The display panel 100 may include a main area MA and a subsidiary area SBA extending from one side of the main area MA.

In an embodiment, the main area MA may be formed in a rectangular plane having shorter sides in a first direction (e.g., the X-axis direction) and longer sides in a second direction (e.g., the Y-axis direction) intersecting the first direction (e.g., the X-axis direction). Each of the corners where the short side in the first direction (e.g., the X-axis direction) meets the longer side in the second direction (e.g., the Y-axis direction) may be rounded with a predetermined curvature or may be a right angle. The shape of the display device 10 when viewed from the top is not necessarily limited to a quadrangular shape, but may be formed in another polygonal shape, circular shape, elliptical shape, etc.

The main area MA may be, but is not necessarily limited to being, formed to be flat. In an embodiment, the main area MA may include curved portions formed at left and right ends thereof. The curved portions may have a predetermined curvature. In addition, the main area MA may be partially or entirely bendable or foldable.

The main area MA may include a display area DA where pixels are formed to display images, and a non-display area NDA around the display area DA (e.g., in a plan view).

In addition to the pixels, scan lines, data lines, and power lines connected to the pixels may be disposed in the display area DA. In an embodiment in which the main area MA includes a curved portion, the display area DA may be disposed on the curved portion. In this embodiment, images of the display panel 100 can also be seen on the curved portion.

The non-display area NDA may be defined as the area from the outer side of the display area DA to the edge of the display panel 100 (e.g., in a plan view). In the non-display area NDA, a scan driver for applying scan signals to scan lines, and link lines connecting the data lines with the display driver circuit 200 may be disposed.

The subsidiary area SBA may protrude from one side of the main area MA. For example, in an embodiment the subsidiary area SBA may protrude from the main area MA in the opposite direction of the second direction (e.g., the Y-axis direction). The length of the subsidiary area SBA in the first direction (e.g., the X-axis direction) may be less than the length of the main area MA in the first direction (e.g., the X-axis direction).

The display driver circuit 200 and the circuit board 300 may be disposed in the subsidiary area SBA.

The display driver circuit 200 may output signals and voltages for driving the display panel 100. For example, the display driver circuit 200 may apply data voltages to the data lines. In addition, the display driver circuit 200 may apply supply voltage to the power line and may apply scan control signals to the scan driver. In an embodiment, the display driver circuit 200 may be implemented as an integrated circuit (IC) and may be mounted on the display panel 10 by a chip on glass (COG) technique, a chip on plastic (COP) technique, or an ultrasonic bonding. It is, however, to be understood that embodiments of the present disclosure are not necessarily limited thereto. For example, the display driver circuit 200 may be mounted on the circuit board 300.

In an embodiment, the circuit board 300 may be attached on the display panel 100 using an anisotropic conductive film. Accordingly, lead lines of the circuit board 300 may be electrically connected to the display panel 100. The circuit board 300 may be a flexible printed circuit board, a rigid printed circuit board, or a flexible film such as a chip on film.

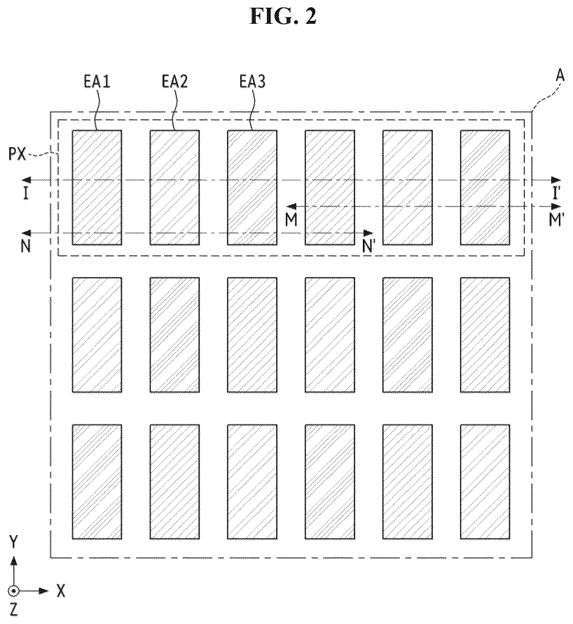

FIG. 2 is a view showing a layout of area A of FIG. 1.

Referring to FIG. 2, a pixel PX may include a first light-emitting area EA1 that emits light of a first color, a second light-emitting area EA2 that emits light of a second color, and a third light-emitting area EA3 that emits light of a third color of light. For example, in an embodiment the first color may be red, the second color may be green, and the third color may be blue. However, embodiments of the present disclosure are not necessarily limited thereto.

In an embodiment, a single pixel PX may include two first light-emitting areas EA1, two second light-emitting areas EA2 and two third light-emitting areas EA3. For example, the first light-emitting area EA1, the second light-emitting area EA2 and the third light-emitting area EA3 located on the left side may emit light during a 2D image display period. The first light-emitting area EA1, the second light-emitting area EA2 and the third light-emitting area EA3 located on the right side may emit light during a 3D image display period.

A first light-emitting area EA1 and a second light-emitting area EA2 may be adjacent to each other (e.g., directly adjacent to each other) in the first direction (e.g., the X-axis direction). A first light-emitting area EA1 and a second light-emitting area EA2 may be adjacent to each other (e.g., directly adjacent to each other) in the second direction (e.g., the Y-axis direction). A second light-emitting area EA2 and a third light-emitting area EA3 may be adjacent to each other (e.g., directly adjacent to each other) in the first direction (e.g., the X-axis direction). A second light-emitting area EA2 and a third light-emitting area EA3 may be adjacent to each other (e.g., directly adjacent to each other) in the second direction (e.g., the Y-axis direction). A third light-emitting area EA3 and a first light-emitting area EA1 may be adjacent to each other (e.g., directly adjacent to each other) in the first direction (e.g., the X-axis direction). A third light-emitting area EA3 and a first light-emitting area EA1 may be adjacent to each other (e.g., directly adjacent to each other) in the second direction (e.g., the Y-axis direction).

Each of the first to third light-emitting areas EA1 to EA3 may have, but is not necessarily limited to, a rectangular shape when viewed from the top. In an embodiment, each of the first to third light-emitting areas EA1 to EA3 may have a polygonal shape, a diamond shape, a circular shape, an elliptical shape, etc., when viewed from the top.

For example, in an embodiment the size (e.g., area in a plan view) of the first light-emitting area EA1, the size (e.g., area in a plan view) of the second light-emitting area EA2 and the size (e.g., area in a plan view) of the third light-emitting area EA3 may be all equal to each other. It should be understood, however, that embodiments of the present disclosure are not necessarily limited thereto. The size of the first light-emitting area EA1, the size of the second light-emitting area EA2, and the size of the third light-emitting area EA3 may be different from one another in some embodiments.

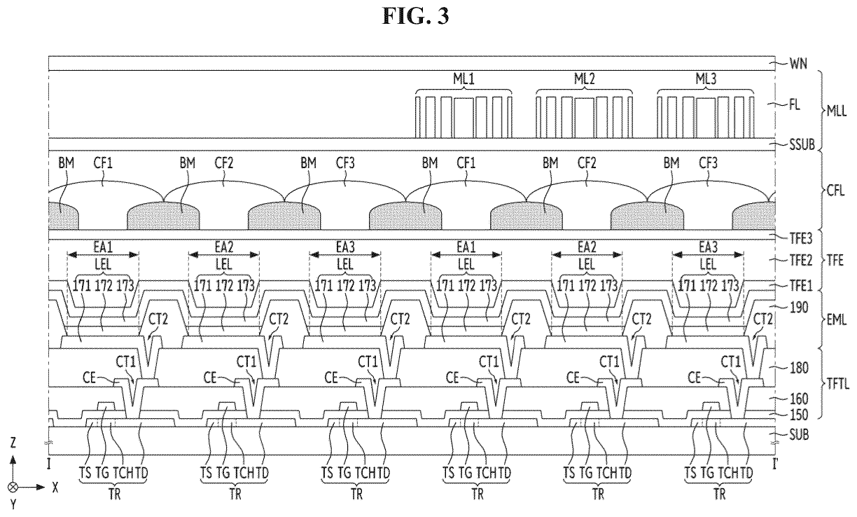

FIG. 3 is a cross-sectional view of the display device, taken along line I-I′ of FIG. 2.

Referring to FIG. 3, in an embodiment the display panel 100 may include a substrate SUB, a thin-film transistor layer TFTL disposed on the substrate SUB, a light-emitting element layer EML, an encapsulation layer TFE, a color filter layer CFL, a metalens layer MLL, and a window member WN.

In an embodiment, the substrate SUB may be made of an insulating material such as glass, quartz and a polymer resin. Alternatively, the substrate SUB may include a metallic material. The substrate SUB may be a rigid substrate or a flexible substrate that can be bent, folded, rolled or otherwise deformed. In an embodiment in which the substrate SUB is a flexible substrate, it may be formed of, but is not necessarily limited to, polyimide (PI).

The thin-film transistor layer TFTL may be disposed on the substrate SUB (e.g., disposed directly thereon in the Z-axis direction). The thin-film transistor layer TFTL may include thin-film transistors TR for each pixel, connecting electrodes CE, and a plurality of insulating films.

In an embodiment, each of the thin-film transistors TR includes a channel TCH, a source electrode TS, a drain electrode TD and a gate electrode TG. The channel TCH, the source electrode TS and the drain electrode TD may be disposed on the substrate SUB (e.g., disposed directly thereon in the Z-axis direction).

A gate insulator 150 may be disposed on (e.g., disposed directly thereon) the channel TCH, the source electrode TS and the drain electrode TD. In an embodiment, the gate insulator 150 may be formed as an inorganic insulating film, for example, a silicon nitride (SiNx) film, a silicon oxide (SiOx) film, a silicon nitride oxide (SiON) film, a titanium oxide (TiOx) film, or an aluminum oxide (AlOx) film.

The gate electrode TG may be disposed on the gate insulator 150 (e.g., disposed directly thereon in the Z-axis direction). The gate electrode TG may overlap with the channel TCH in a third direction (e.g., the Z-axis direction). In an embodiment, the gate electrode GT may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

An interlayer dielectric film 160 may be disposed on (e.g., disposed directly thereon) the gate electrode TG and the gate insulator 150. In an embodiment, the interlayer dielectric film 160 may be formed of an inorganic layer, for example, a silicon nitride layer, a silicon oxynitride layer, a silicon oxide layer, a titanium oxide layer, or an aluminum oxide layer. The interlayer dielectric film 160 may include a plurality of inorganic films.

The connecting electrodes CE may be disposed on the interlayer dielectric film 160 (e.g., disposed directly thereon in the Z-axis direction). In an embodiment, connecting electrodes CE may be connected to a drain electrode TD through a first contact hole CT1 penetrating the gate insulator 150 and the interlayer dielectric film 160. In an embodiment, the connecting electrodes CE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A protective film 180 may be disposed on (e.g., disposed directly thereon) the connecting electrodes CE and the interlayer dielectric film 160 to provide a flat surface over the thin-film transistor TR and protect the thin-film transistor TR. In an embodiment, the protective film 180 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The light-emitting element layer EML may be disposed on the thin-film transistor layer TFTL (e.g., disposed directly thereon in the Z-axis direction). The light-emitting element layer EML may be disposed in the display area DA of the main area MA. In an embodiment, the light-emitting element layer EML includes light-emitting elements LEL disposed in first to third light-emitting areas EA1 to EA3, and a pixel-defining layer 190 defining the first to third light-emitting areas EA1 to EA3. Each of the light-emitting elements LEL includes a pixel electrode 171, an emissive layer 172, and a common electrode 173.

In an embodiment, a pixel electrode layer may be disposed on the protective film 180 (e.g., disposed directly thereon in the Z-axis direction). The pixel electrode layer includes the pixel electrode 171. In an embodiment, a pixel electrode 171 may be connected to a connecting electrode CE through a second contact hole CT2 penetrating the protective film 180. In an embodiment, in the top-emission structure where light exits from the emissive layer 172 towards the common electrode 173, the pixel electrode 171 may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of APC alloy and ITO (ITO/APC/ITO) in order to increase the reflectivity. The APC alloy is an alloy of silver (Ag), palladium (Pd) and copper (Cu).

The pixel-defining layer 190 may be disposed on (e.g., disposed directly thereon) a portion of a pixel electrode 171. The pixel-defining layer 190 may define the light-emitting areas EA1 to EA3 of the pixels PX. The pixel-defining layer 190 may be formed on the protective film 180 and may include an opening exposing a part of the pixel electrodes 171. For example, the pixel-defining layer 190 may cover edges of the pixel electrodes 171 and the opening may expose a central portion of the pixel electrodes 171. In an embodiment, the pixel-defining layer 190 may be formed of an organic layer such as an acryl resin, an epoxy resin, a phenolic resin, a polyamide resin and a polyimide resin.

The common electrode 173 may be disposed on the pixel-defining layer 190 and the emissive layer 172 (e.g., in the Z-axis direction). The common electrode 173 may be formed to cover the emissive layer 172. In an embodiment, the common electrode 173 may be a common layer formed across the light-emitting areas EA1 to EA3.

The encapsulation layer TFE may be disposed on the light-emitting element layer EML (e.g., disposed directly thereon in the Z-axis direction). The encapsulation layer TFE may be disposed in the display area DA and the non-display area NDA of the main area MA. In a embodiment, the encapsulation layer TFE may include at least one inorganic film and at least one organic film for encapsulating the light-emitting element layer EML.

For example, in an embodiment the encapsulation layer TFE may include a first inorganic encapsulation layer TFE1 and a second inorganic encapsulation layer TFE3 that serve to prevent oxygen or moisture from permeating into the light-emitting element layer EML. The first inorganic encapsulation layer TFE1 and the second inorganic encapsulation layer TFE3 may be, but is not necessarily limited to, a silicon nitride layer, a silicon oxynitride layer, a silicon oxide layer, a titanium oxide layer, or an aluminum oxide layer.

In addition, the encapsulation layer TFEL may include a first organic encapsulation layer TFE2 that protects the light-emitting element layer EML from particles such as dust. The first organic encapsulation layer TFE2 may be disposed between the first inorganic encapsulation layer TFE1 and the second inorganic encapsulation layer TFE3 (e.g., in the Z-axis direction). The first organic encapsulation layer TFE2 may be, but is not necessarily limited to, an acryl resin, an epoxy resin, a phenolic resin, a polyamide resin, a polyimide resin, etc.

The color filter layer CFL may be disposed on the encapsulation layer TFE (e.g., disposed directly thereon in the Z-axis direction). The color filter layer CFL may be disposed in the display area DA of the main area MA. The color filter layer CFL may transmit light emitted from the light-emitting element layer EML. The color filter layer CFL includes first to third color filters CF1 to CF3 and a black matrix BM.

The first color filter CF1 may transmit light of the first color. The first color filter CF1 may overlap (e.g., in the Z-axis direction) with the first light-emitting area EA1 that emits light of the first color. The second color filter CF2 may transmit light of the second color. The second color filter CF2 may overlap (e.g., in the Z-axis direction) with the second light-emitting area EA2 that emits light of the second color. The third color filter CF3 may transmit light of the third color. The third color filter CF3 may overlap (e.g., in the Z-axis direction) with the third light-emitting area EA3 that emits light of the third color.

The black matrix BM may be disposed between the first to third color filters CF1 to CF3 and may be arranged in the X-axis direction. The black matrix BM may overlap (e.g., in the Z-axis direction) with the pixel-defining layer 190. The edges of the black matrix BM may or may not overlap (e.g., in the Z-axis direction) with the edges of the first to third light-emitting areas EA1 to EA3.

The metalens layer MLL may be disposed on the color filter layer CFL (e.g., disposed directly thereon in the Z-axis direction). The metalens layer MLL may be disposed in the display area DA of the main area MA. The metalens layer MLL may refract light emitted from the light-emitting element layer EML. In an embodiment, the metalens layer MLL may include a base substrate SSUB and first to third metalens ML1 to ML3. According to some embodiments of the present disclosure, the base substrate SSUB of the metalens layer MLL may not be included in the metalens layer MLL.

The base substrate SSUB may be disposed on the color filter layer CFL (e.g., disposed directly thereon in the Z-axis direction). In an embodiment, the base substrate SSUB may include a glass, plastic, or polymer material that transmits light.

The first to third metalens ML1 to ML3 may be disposed on the base substrate SSUB. The first metalens ML1 may refract light of the first color. The first metalens ML1 may overlap (e.g., in a thickness direction of the substrate SUB, such as the Z-axis direction) with some of the first light-emitting areas EA1 that emit light of the first color. The second metalens ML2 may refract light of the second color. The second metalens ML2 may overlap (e.g., in the Z-axis direction) with some of the second light-emitting areas EA2 that emit light of the second color. The third metalens ML3 may refract light of the third color. The third metalens ML3 may overlap (e.g., in the Z-axis direction) with some of the third light-emitting areas EA3 that emit light of the third color.

In an embodiment, each of the first to third metalenses ML1 to ML3 may include a nanostructure that is smaller than the wavelength of light it transmits. The nanostructure may have various shapes, such as a circular column, a rectangular column, and a cross column. For example, the nanostructure may have a circular column shape with isotropic refractive index.

For example, the first metalens ML1 may include a first nanostructure having a first spacing, a first width, and a first height. The second metalens ML2 may include a second nanostructure having a second spacing, a second width, and a second height. The third metalens ML3 may include a third nanostructure having a third spacing, a third width, and a third height. In an embodiment, the first nanostructure, the second nanostructure, and the third nanostructure may have different nanostructures from one another.

For example, in an embodiment the nanostructure may include at least one of: titanium dioxide (TiO₂), silicon dioxide (SiO₂), silicon nitride (Si₃N₄), silicon oxynitride (SiON), silicon nitride (SiNx), silver (Ag), and aluminum (Al). For example, the refractive index of the nanostructure may be in a range from about 1.8 to about 2.0.

The metalens layer MLL may further include a filler FL disposed between the nanostructures of the first to third metalens ML1 to ML3 and between the base substrate SSUB and the window member WN. In an embodiment, the filler FL may include an acryl resin, an epoxy resin, a phenolic resin, a polyamide resin, a polyimide resin, etc. The refractive index of the filler FL may be lower than that of the first to third metalenses ML1 to ML3. For example, in an embodiment the refractive index of the filler FL may range from, but is not necessarily limited to, about 1.4 to about 1.6.

The window member WN may be disposed on the metalens layer MLL (e.g., disposed directly thereon in the Z-axis direction). The window member WN can protect the upper portion of the display panel 100. In an embodiment, the window member WN may be attached on the metalens layer MLL by a transparent adhesive member such as an optically clear adhesive (OCA) film and an optically clear resin (OCR). The window member WN may be either an inorganic material such as glass or an organic material such as plastic and polymer material.

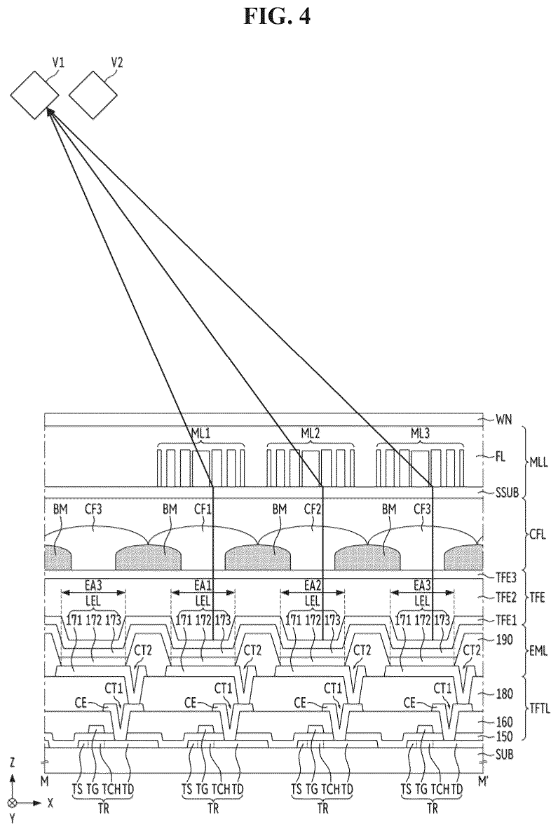

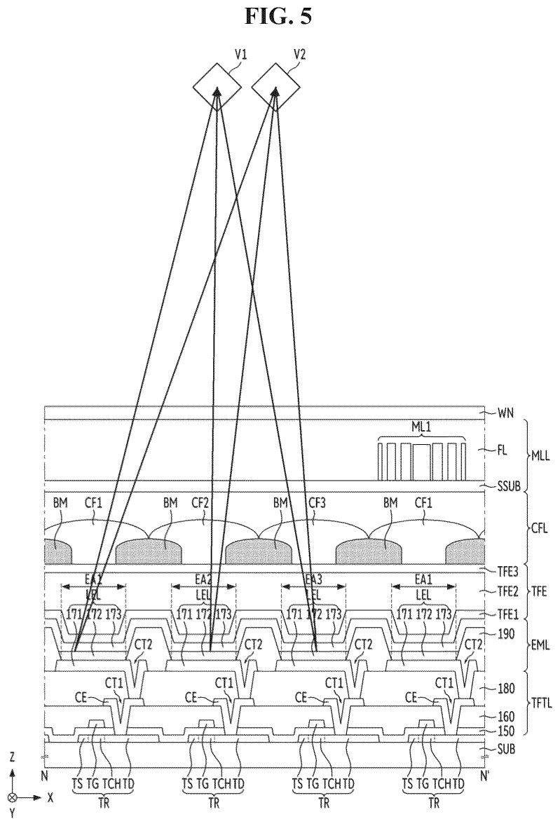

FIG. 4 is a cross-sectional view of the display device, taken along line M-M′ of FIG. 2. FIG. 5 is a cross-sectional view of the display device, taken along line N-N′ of FIG. 2.

FIG. 4 shows an example of an operation of the display panel 100 during a 3D image display period. FIG. 5 shows an example of an operation of the display panel 100 during a 2D image display period.

Light output from the display panel 100 may propagate towards at least one of a plurality of view areas. Although only a first view area V1 and a second view area V2 are shown in FIGS. 4 and 5 as an example, it is to be understood that the number of view areas is not necessarily limited to two.

Referring to FIG. 4, in an embodiment one of the plurality of first light-emitting areas EA1 may emit light of the first color during a 3D image display period. One of the plurality of second light-emitting areas EA2 may emit light of the second color during the 3D image display period. One of the plurality of third light-emitting areas EA3 may emit light of the third color during the 3D image display period.

In an embodiment, during the 3D image display period, light of the first color output from one of the first light-emitting areas EA1 may pass through the first color filter CF1 that transmits light of the first color. The light passing through the first color filter CF1 may be refracted through the first metalens ML1. In this manner, during the 3D image display period, the light output from one of the first light-emitting areas EA1 may propagate to the first view area V1.

In an embodiment, during the 3D image display period, light of the second color output from one of the second light-emitting areas EA2 may pass through the second color filter CF2 that transmits light of the second color. The light passing through the second color filter CF2 may be refracted through the second metalens ML2. In this manner, during the 3D image display period, the light output from one of the second light-emitting areas EA2 may propagate to the first view area V1.

In an embodiment, during the 3D image display period, light of the third color output from one of the third light-emitting areas EA3 may pass through the third color filter CF3 that transmits light of the third color. The light passing through the third color filter CF3 may be refracted through the third metalens ML3. In this manner, during the 3D image display period, the light output from one of the third light-emitting areas EA3 may propagate to the first view area V1.

In the first view area V1, light output from one of the first light-emitting areas EA1, one of the second light-emitting areas EA2, and one of the third light-emitting areas EA3 is observed. On the other hand, in the second view area V2, light output from one of the first light-emitting areas EA1, one of the second light-emitting areas EA2, and one of the third light-emitting areas EA3 is not observed. Accordingly, there is a difference between the image provided to the first view area V1 and the image provided to the second view area V2, so that the display device 10 of the present disclosure can display a 3D image.

In the example shown in FIG. 4, the light output from one first light-emitting area EA1, one second light-emitting area EA2, and one third light-emitting area EA3 propagates to the first view area V1. This is an example where one first light-emitting area EA1, one second light-emitting area EA2 and one third light-emitting area EA3 are included in the same pixel PX. It is to be noted that the light output from not all of the pixels PX propagates to the first view area V1 during the 3D image display period according to this embodiment. Light output from other pixels PX not shown in FIG. 4 during the 3D image display period may propagate to the second view area V2.

Referring to FIG. 5, another one of the plurality of first light-emitting areas EA1 may emit light of the first color during a 2D image display period. Another one of the plurality of second light-emitting areas EA2 may emit light of the second color during the 2D image display period. Another one of the plurality of third light-emitting areas EA3 may emit light of the third color during the 2D image display period.

In an embodiment, during the 2D image display period, the light of the first color output from another one of the first light-emitting areas EA1 may pass through the first color filter CF1 that transmits light of the first color. The light passing through the first color filter CF1 may propagate to both the first view area V1 and the second view area V2 without passing through the metalenses ML1 to ML3.

In an embodiment, during the 2D image display period, the light of the second color output from another one of the second light-emitting areas EA2 may pass through the second color filter CF2 that transmits light of the second color. The light passing through the second color filter CF2 may propagate to both the first view area V1 and the second view area V2 without passing through the metalenses ML1 to ML3.

In an embodiment, during the 2D image display period, light of the third color output from another one of the third light-emitting areas EA3 may pass through the third color filter CF3 that transmits light of the third color. The light passing through the third color filter CF3 may propagate to both the first view area V1 and the second view area V2 without passing through the metalenses ML1 to ML3.

In both the first view area V1 and the second view area V2, light output from another first light-emitting area EA1, another second light-emitting area EA2 and another third light-emitting area EA3 is observed. Accordingly, the image provided to the first view area V1 is identical to the image provided to the second view area V2, so that the display device 10 of the present disclosure can display a 2D image.

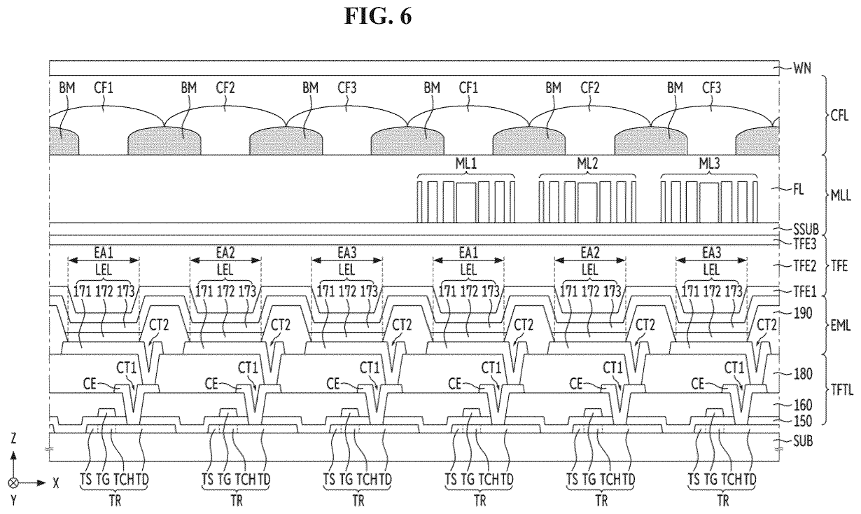

FIG. 6 is a cross-sectional view of the display device, taken along line I-I′ of FIG. 2. The following description will focus on differences and the redundant description may be omitted for economy of explanation.

In an embodiment, the display panel 100 may include a substrate SUB, a thin-film transistor layer TFTL, an light-emitting element layer EML, an encapsulation layer TFE, a metalens layer MLL, and a color filter layer CFL disposed on the substrate SUB.

The detailed configurations of the substrate SUB, the thin-film transistor layer TFTL, the light-emitting element layer EML, the metalens layer MLL and the color filter layer CFL may be identical to those described above with reference to FIG. 3.

Referring to FIG. 6, the base substrate SSUB of the metalens layer MLL may be disposed on the encapsulation layer TFE (e.g., disposed directly thereon in the Z-axis direction). First to third metalenses ML1 to ML3 may be disposed on the base substrate SSUB (e.g., disposed directly thereon in the Z-axis direction).

The first metalens ML1 may overlap with one of the first light-emitting areas EA1 in the third direction (e.g., the Z-axis direction). The edges of the first metalens ML1 may overlap with the pixel-defining layer 190 in the third direction (e.g., the Z-axis direction).

The second metalens ML2 may overlap with one of the second light-emitting areas EA2 in the third direction (e.g., the Z-axis direction). The second metalens ML2 may be adjacent to (e.g., directly adjacent thereto) the first metalens ML1 in the first direction (e.g., the X-axis direction). The second light-emitting area EA2 overlapping with the second metalens ML2 may be included in the same pixel PX as the first light-emitting area EA1 overlapping with the adjacent first metalens ML1. The edges of the second metalens ML2 may overlap with the pixel-defining layer 190 in the third direction (e.g., the Z-axis direction).

The third metalens ML3 may overlap with one of the third light-emitting areas EA3 in the third direction (e.g., the Z-axis direction). The third metalens ML3 may be adjacent to (e.g., directly adjacent thereto) the second metalens ML2 in the first direction (e.g., the X-axis direction). The third light-emitting area EA3 overlapping with the third metalens ML3 may be included in the same pixel PX as the second light-emitting area EA2 overlapping with the second metalens ML2 adjacent to the third metalens ML3. The edges of the third metalens ML3 may overlap with the pixel-defining layer 190 in the third direction (e.g., the Z-axis direction).

In an embodiment, the metalens layer MLL may be filled with a filler FL. The filler FL may be disposed between a first metalens ML1 and a second metalens ML2, between the second metalens ML2 and a third metalens ML3, between the third metalens ML3 and a first metalens ML1, and between the nanostructures of each of the metalenses ML1 to ML3.

A color filter layer CFL may be disposed on the filler FL of the metalens layer MLL (e.g., disposed directly thereon in the Z-axis direction). In an embodiment, the color filter layer CFL may include a plurality of first color filters CF1, a plurality of second color filters CF2, a plurality of third color filters CF3, and a black matrix BM disposed between the plurality of first to third color filters CF1 to CF3 and arranged in the X-axis direction.

One of the plurality of first color filters CF1 may overlap with the first metalens ML1 in the third direction (e.g., the Z-axis direction). One first color filter CF1 may overlap with the first light-emitting area EA1 in the third direction (e.g., the Z-axis direction).

Another one of the plurality of first color filters CF1 may not overlap with the first metalens ML1 in the third direction (e.g., the Z-axis direction). Another first color filter CF1 may overlap with the first light-emitting area EA1 in the third direction (e.g., the Z-axis direction).

One of the plurality of second color filters CF2 may overlap with the second metalens ML2 in the third direction (e.g., the Z-axis direction). One second color filter CF2 may overlap with the second light-emitting area EA2 in the third direction (e.g., the Z-axis direction).

Another one of the plurality of second color filters CF2 may not overlap with the second metalens ML2 in the third direction (e.g., the Z-axis direction). Another one second color filter CF2 may overlap with the second light-emitting area EA2 in the third direction (e.g., the Z-axis direction).

One of the plurality of third color filters CF3 may overlap with the third metalens ML3 in the third direction (e.g., the Z-axis direction). One third color filter CF3 may overlap with the third light-emitting area EA3 in the third direction (e.g., the Z-axis direction).

Another one of the plurality of third color filters CF3 may overlap with the third metalens ML3 in the third direction (e.g., the Z-axis direction). Another third color filter CF3 may overlap with the third light-emitting area EA3 in the third direction (e.g., the Z-axis direction).

A window member WN may be disposed on the color filter layer CFL (e.g., disposed directly thereon in the Z-axis direction).

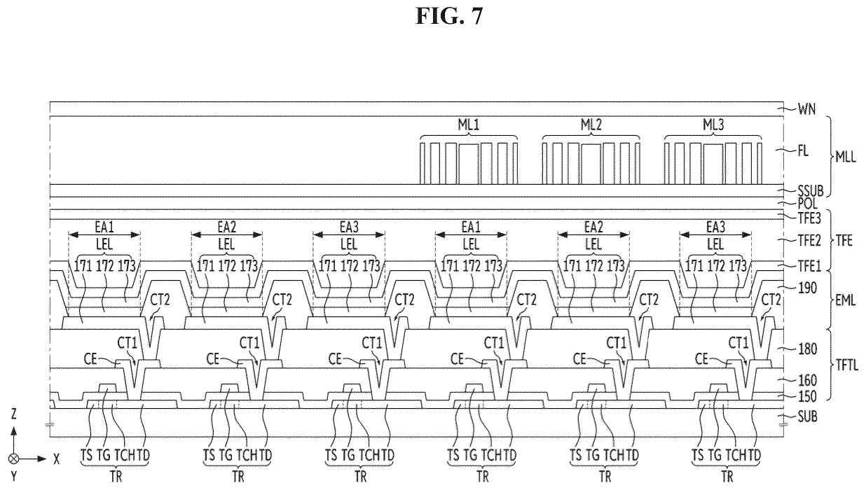

FIG. 7 is a cross-sectional view of the display device, taken along line I-I′ of FIG. 2. The following description will focus on differences and the redundant description may be omitted for economy of explanation.

Referring to FIG. 7, in an embodiment the display panel 100 may include a substrate SUB, a thin-film transistor layer TFTL, an light-emitting element layer EML, an encapsulation layer TFE, a polarizing member POL, a metalens layer MLL, and a window member WN disposed on the substrate SUB.

The detailed configurations of the substrate SUB, the thin-film transistor layer TFTL, the light-emitting element layer EML, the encapsulation layer TFE, the metalens layer MLL and the window member WN may be identical to those described above with reference to FIG. 3.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the polarizing member POL may be disposed on the encapsulation layer TFE (e.g., disposed directly thereon in the Z-axis direction). The metalens layer MLL may be disposed on the polarizing member POL (e.g., disposed directly thereon in the Z-axis direction), and the window member WN may be disposed on the metalens layer MLL (e.g., disposed directly thereon in the Z-axis direction).

In an embodiment, the lower surface of the polarizing member POL may be in direct contact with the encapsulation layer TFE. The upper surface of the polarizing member POL may be in direct contact with the metalens layer MLL. The polarizing member POL may transmit light vibrating in a particular direction and block light vibrating in a direction different from the direction. The polarizing member POL can prevent light propagating from the outside to the display panel 100 from being reflected.

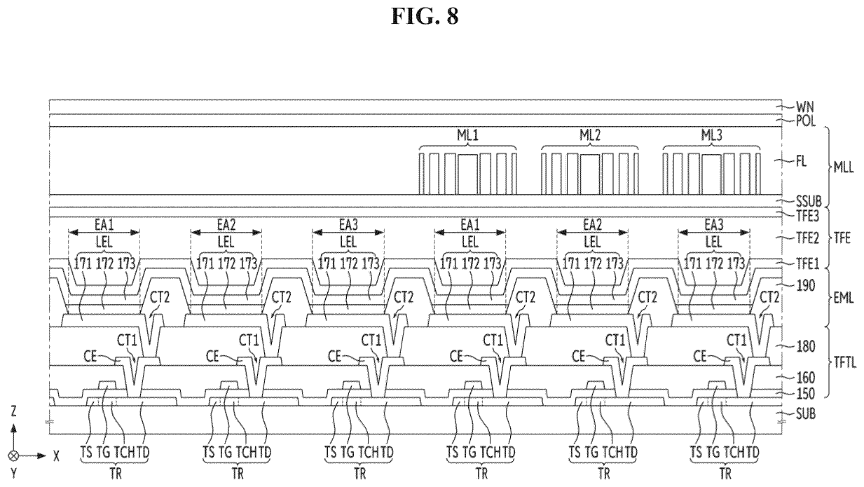

FIG. 8 is a cross-sectional view of the display device, taken along line I-I′ of FIG. 2. The following description will focus on differences and the redundant description may be omitted for economy of explanation.

Referring to FIG. 8, in an embodiment the display panel 100 may include a substrate SUB, a thin-film transistor layer TFTL, an light-emitting element layer EML, an encapsulation layer TFE, a metalens layer MLL, a polarizing member POL, and a window member WN disposed on the substrate SUB.

The detailed configurations of the substrate SUB, the thin-film transistor layer TFTL, the light-emitting element layer EML, the encapsulation layer TFE, the metalens layer MLL and the window member WN may be identical to those described above with reference to FIG. 3. The polarizing member POL may be identical to the polarizing member POL described above with reference to FIG. 7.

FIG. 8 is different from FIG. 7 in that the positions of the polarizing member POL and the metalens layer MLL are switched in the vertical direction (e.g., the Z-axis direction). The polarizing member POL may be disposed on the metalens layer MLL (e.g., disposed directly thereon in the Z-axis direction). In this manner, the polarizing member POL can effectively reduce the reflection of light incident on the display panel 100 from the outside (e.g., the external environment).

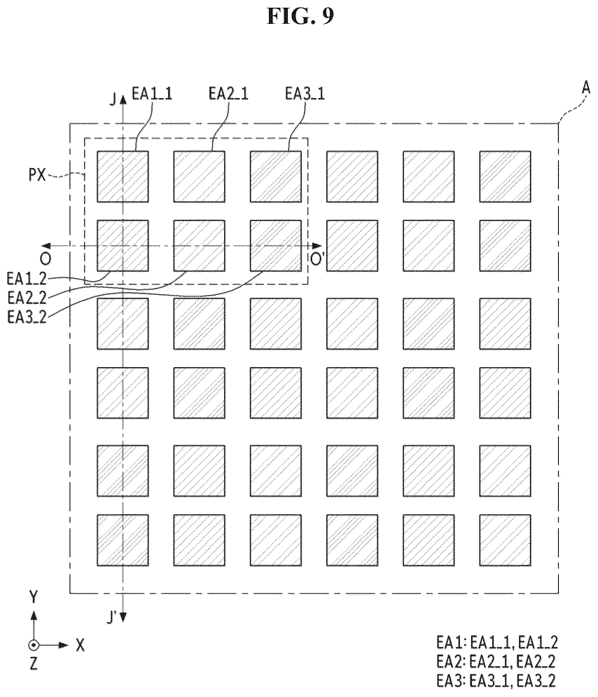

FIG. 9 is a view showing a layout of area A of FIG. 1. The following description will focus on differences and the redundant description may be omitted for economy of explanation.

Referring to FIG. 9, in an embodiment a pixel PX may include a first light-emitting area EA1, a second light-emitting area EA2, and a third light-emitting area EA3.

The first light-emitting area EA1 may include a plurality of first subsidiary light-emitting areas EA1_1 and EA1_2. The second light-emitting area EA2 may include a plurality of second subsidiary light-emitting areas EA2_1 and EA2_2. The third light-emitting area EA3 may include a plurality of third subsidiary light-emitting areas EA3_1 and EA3_2.

In a single pixel PX, a plurality of first subsidiary light-emitting areas EA1_1 and EA1_2 may be adjacent to each other (e.g., directly adjacent to each other in a direction parallel to an upper surface of the substrate SUB, such as the Y-axis direction). In a single pixel PX, a plurality of second subsidiary light-emitting areas EA2_1 and EA2_2 may be adjacent to each other (e.g., directly adjacent to each other in the Y-axis direction). In a single pixel PX, a plurality of third subsidiary light-emitting areas EA3_1 and EA3_2 may be adjacent to each other (e.g., directly adjacent to each other in the Y-axis direction). In the example shown in FIG. 9, two first subsidiary light-emitting areas EA1_1 and EA1_2 are adjacent to each other in the second direction (e.g., the Y-axis direction), two second subsidiary light-emitting areas EA2_1 and EA2_2 are adjacent to each other in the second direction (e.g., the Y-axis direction), and two third subsidiary light-emitting areas EA3_1 and EA3_2 are adjacent to each other in the second direction (e.g., the Y-axis direction). The first subsidiary light-emitting area EA1_1, the second subsidiary light-emitting area EA2_1 and the third subsidiary light-emitting area EA3_1 may be alternately arranged in the X-axis direction parallel to an upper surface of the substrate SUB and perpendicular to the Y-axis direction. The first subsidiary light-emitting area EA1_2, the second subsidiary light-emitting area EA2_2 and the third subsidiary light-emitting area EA3_2 may be alternately arranged in the X-axis direction parallel to an upper surface of the substrate SUB and perpendicular to the Y-axis direction. It should be understood, however, that embodiments of the present disclosure are not necessarily limited thereto.

In an embodiment, in a single pixel PX, one first subsidiary light-emitting area EA1_1 of the two first subsidiary light-emitting areas EA1_1 and EA1_2 may operate in a 2D image display period, while the other first subsidiary light-emitting area EA1_2 may operate in a 3D image display period. In a single pixel PX, one second subsidiary light-emitting area EA2_1 of the two second subsidiary light-emitting areas EA2_1 and EA2_2 may operate in a 2D image display period, while the other second subsidiary light-emitting area EA2_2 may operate in a 3D image display period. In a single pixel PX, one third subsidiary light-emitting area EA3_1 of the two third subsidiary light-emitting areas EA3_1 and EA3_2 may operate in a 2D image display period, while the other third subsidiary light-emitting area EA3_2 may operate in a 3D image display period.

Compared with FIG. 2, the width of each of the first subsidiary light-emitting areas EA1_1 and EA1_2, the second subsidiary light-emitting areas EA2_1 and EA2_2, and the third subsidiary light-emitting areas EA3_1 and EA3_2 may be less than that of FIG. 2. For example, the sum of the widths (e.g., lengths in the Y-axis direction) of two first subsidiary light-emitting areas EA1_1 and EA1_2 of FIG. 9 may be equal to or different from the width (e.g., length in the Y-axis direction) of one first light-emitting area EA1 of FIG. 2. In this manner, it is possible to prevent degradation of resolution occurring during the 2D image display period and the 3D image display period.

In an embodiment, the first light-emitting areas EA1′, the second light-emitting areas EA2′ and the third light-emitting areas EA3′ may be arranged repeatedly and sequentially in the first direction (e.g., the X-axis direction). The first light-emitting areas EA1, the second light-emitting areas EA2 and the third light-emitting areas EA3 may be arranged repeatedly and sequentially in the second direction (e.g., the Y-axis direction).

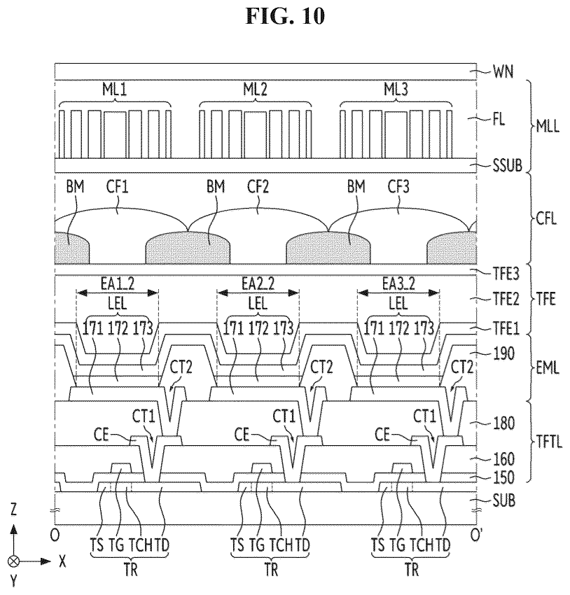

FIG. 10 is a cross-sectional view of the display device, taken along line O-O′ of FIG. 9. The following description will focus on differences and the redundant description may be omitted for economy of explanation.

Referring to FIG. 10, in an embodiment the display panel 100 may include a substrate SUB, a thin-film transistor layer TFTL, an encapsulation layer TFE, a color filter layer CFL, a metalens layer MLL, and a window member WN disposed on the substrate SUB.

The detailed configurations of the substrate SUB, the thin-film transistor layer TFTL, the light-emitting element layer EML, the encapsulation layer TFE, the color filter layer CFL, the metalens layer MLL and the window member WN may be identical to those described above with reference to FIG. 3.

For a single pixel PX, a first metalens ML1, a second metalens ML2 and a third metalens ML3 may be adjacent to one another (e.g., directly adjacent to one another) in the first direction (e.g., the X-axis direction).

The first metalens ML1 may overlap with the first color filter CF1 and another first subsidiary light-emitting area EA1_2 in the third direction (e.g., the Z-axis direction). The second metalens ML2 may overlap with the second color filter CF2 and another second subsidiary light-emitting area EA2_2 in the third direction (e.g., the Z-axis direction). The third metalens ML3 may overlap with the third color filter CF3 and another third subsidiary light-emitting area EA3_2 in the third direction (e.g., the Z-axis direction).

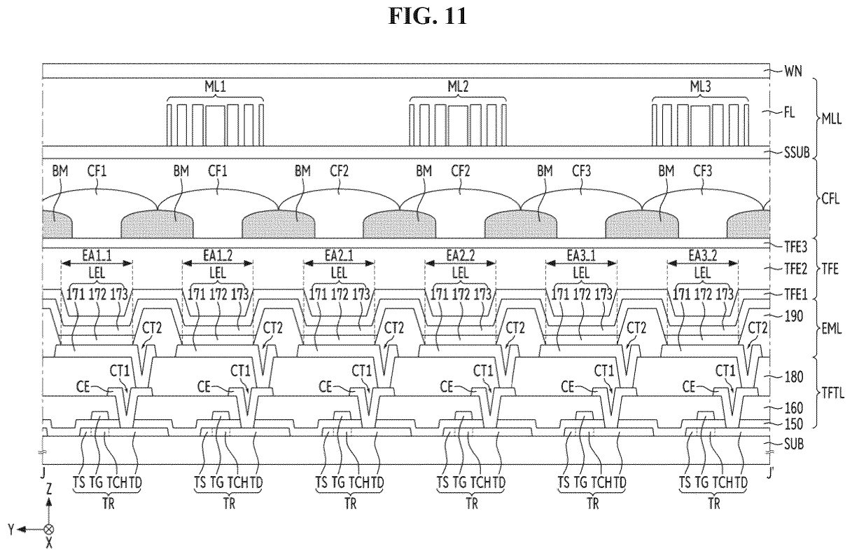

FIG. 11 is a cross-sectional view of the display device, taken along line J-J′ of FIG. 9. The following description will focus on differences and the redundant description may be omitted for economy of explanation.

Referring to FIG. 11, in an embodiment the display panel 100 may include a substrate SUB, a thin-film transistor layer TFTL disposed on the substrate SUB, an light-emitting element layer EML, an encapsulation layer TFE, a color filter layer CFL, a metalens layer MLL, and a window member WN.

The thin-film transistor layer TFTL may be disposed on the substrate SUB (e.g., disposed directly thereon in the Z-axis direction), and the light-emitting element layer EML may be disposed on the thin-film transistor layer TFTL(e.g., disposed directly thereon in the Z-axis direction). The encapsulation layer TFE may be disposed on the light-emitting element layer EML (e.g., disposed directly thereon in the Z-axis direction), and the color filter layer CFL may be disposed on the encapsulation layer TFE (e.g., disposed directly thereon in the Z-axis direction). The metalens layer MLL may be disposed on the color filter layer CFL (e.g., disposed directly thereon in the Z-axis direction), and the window member WN may be disposed on the metalens layer MLL (e.g., disposed directly thereon in the Z-axis direction).

In an embodiment, a plurality of first subsidiary light-emitting areas EA1_1 and EA1_2 may be adjacent to each other (e.g., directly adjacent to each other) in the second direction (e.g., the Y-axis direction). A plurality of second subsidiary light-emitting areas EA2_1 and EA2_2 may be adjacent to each other (e.g., directly adjacent to each other) in the second direction (e.g., the Y-axis direction). A plurality of third subsidiary light-emitting areas EA3_1 and EA3_2 may be adjacent to each other (e.g., directly adjacent to each other) in the second direction (e.g., the Y-axis direction).

A plurality of first subsidiary light-emitting areas EA1_1 and EA1_2 may overlap with the first color filters CF1 in the third direction (e.g., the Z-axis direction). A black matrix BM may be disposed between the first color filters CF1 and arranged in the Y-axis direction.

The first metalens ML1 may overlap with one of the first color filters CF1 and another first subsidiary light-emitting area EA1_2 in the third direction (e.g., the Z-axis direction).

A plurality of second subsidiary light-emitting areas EA2_1 and EA2_2 may overlap with the second color filters CF2 in the third direction (e.g., the Z-axis direction). A black matrix BM may be disposed between the second color filters CF2 (e.g., in the Y-axis direction).

The second metalens ML2 may overlap with one of the second color filters CF2 and another second subsidiary light-emitting area EA2_2 in the third direction (e.g., the Z-axis direction).

A plurality of third subsidiary light-emitting areas EA3_1 and EA3_2 may overlap with the third color filters CF3 in the third direction (e.g., the Z-axis direction). A black matrix BM may be disposed between the third color filters CF3 (e.g., in the Y-axis direction).

The third metalens ML3 may overlap with one of the third color filters CF3 and another third subsidiary light-emitting area EA3_2 in the third direction (e.g., the Z-axis direction).

Compared with FIG. 10, the distance between the first metalens ML1 and the second metalens ML2 adjacent to the first metalens ML1 in the first direction (e.g., the X-axis direction) may be less than the distance between the first metalens ML1 and the second metalens ML2 adjacent to the first metalens ML1 in the second direction (e.g., the Y-axis direction).

The distance between the second metalens ML2 and the third metalens ML3 adjacent to the second metalens ML2 in the first direction (e.g., the X-axis direction) may be less than the distance between the second metalens ML2 and the third metalens ML3 adjacent to the second metalens ML2 in the second direction (e.g., the Y-axis direction).

In the second direction (e.g., the Y-axis direction), a second subsidiary light-emitting area EA2_1 may be disposed between the first metalens ML1 and the second metalens ML2 adjacent to the first metalens ML1.

In the second direction (e.g., the Y-axis direction), a third subsidiary light-emitting area EA3_1 may be disposed between the second metalens ML2 and the third metalens ML3 adjacent to the second metalens ML2.

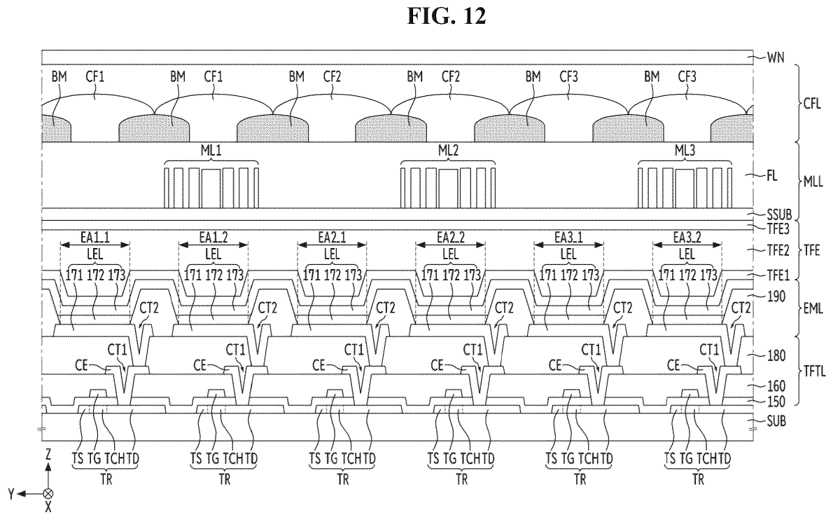

FIG. 12 is a cross-sectional view of the display device, taken along line J-J′ of FIG. 9. The following description will focus on differences and the redundant description may be omitted for economy of explanation.

Referring to FIG. 12, in an embodiment the display panel 100 may include a substrate SUB, a thin-film transistor layer TFTL disposed on the substrate SUB, an light-emitting element layer EML, an encapsulation layer TFE, a metalens layer MLL, a color filter layer CFL, and a window member WN.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the metalens layer MLL may be disposed on the encapsulation layer TFE (e.g., disposed directly thereon in the Z-axis direction). A color filter layer CFL may be disposed on the metalens layer MLL (e.g., disposed directly thereon in the Z-axis direction), and a window member WN may be disposed on the color filter layer CFL (e.g., disposed directly thereon in the Z-axis direction).

Compared to FIG. 11, the positions of the metalens layer MLL and the color filter layer CFL may be switched in the vertical direction (e.g., the Z-axis direction). In an embodiment, the lower surface of the metalens layer MLL may be in direct contact with the encapsulation layer TFE, and the upper surface of the metalens layer MLL may be in direct contact with the lower surface of the color filter layer CFL.

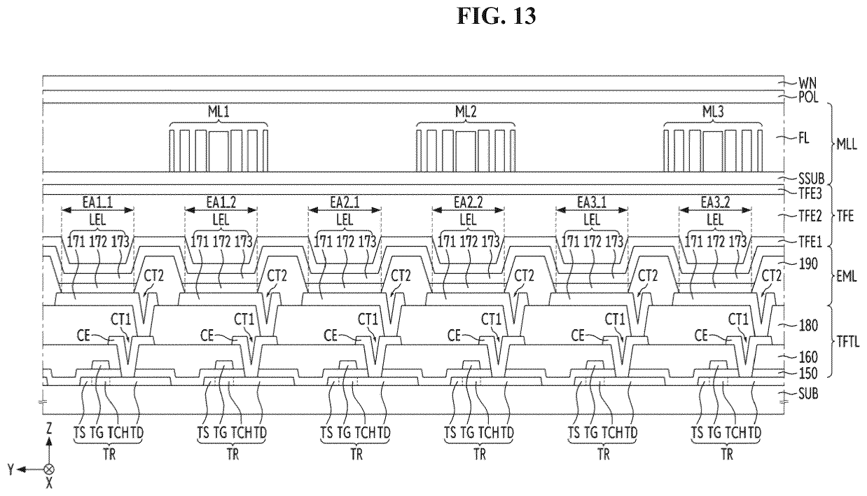

FIG. 13 is a cross-sectional view of the display device, taken along line J-J′ of FIG. 9. The following description will focus on differences and the redundant description may be omitted for economy of explanation.

Referring to FIG. 13, in an embodiment the thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the metalens layer MLL may be disposed on the encapsulation layer TFE (e.g., disposed directly thereon in the Z-axis direction). A polarizing member POL may be disposed on the metalens layer MLL (e.g., disposed directly thereon in the Z-axis direction), and a window member WN may be disposed on the polarizing member POL (e.g., disposed directly thereon in the Z-axis direction).

Compared to FIG. 12, the display device of FIG. 13 may include the polarizing member POL instead of the color filter layer CFL of FIG. 12. The polarizing member POL can suppress reflection of light incident on the display panel 100 from the outside (e.g., the external environment) instead of the color filter layer CFL.

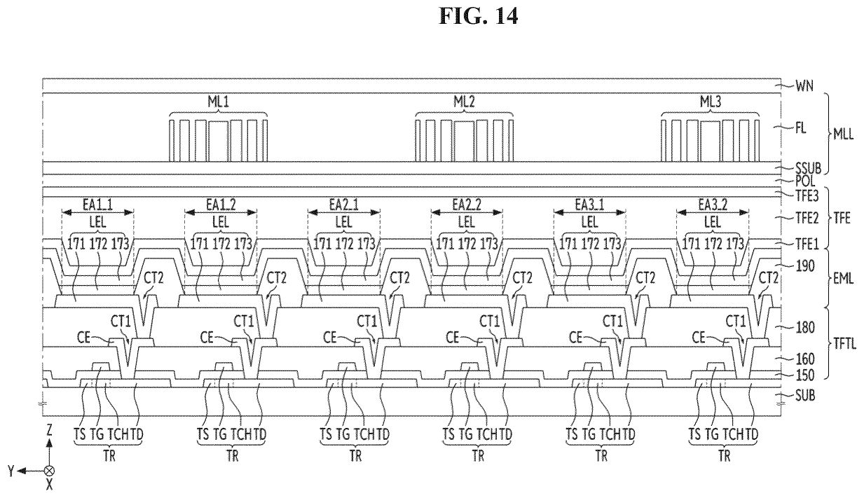

FIG. 14 is a cross-sectional view of the display device, taken along line J-J′ of FIG. 9. The following description will focus on differences and the redundant description may be omitted for economy of explanation.

Referring to FIG. 14, the thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the polarizing member POL may be disposed on the encapsulation layer TFE (e.g., disposed directly thereon in the Z-axis direction). The metalens layer MLL may be disposed on the polarizing member POL (e.g., disposed directly thereon in the Z-axis direction), and the window member WN may be disposed on the metalens layer MLL (e.g., disposed directly thereon in the Z-axis direction).

Compared to FIG. 13, the positions of the metalens layer MLL and the polarizing member POL may be switched in the vertical direction (e.g., the Z-axis direction). In an embodiment, the lower surface of the metalens layer MLL may be in direct contact with the upper surface of the polarizing member POL, and the upper surface of the metalens layer MLL may be in direct contact with the lower surface of the window member WN.

According to this embodiment where the polarizing member POL is disposed on the lower surface of the metalens layer MLL, light emitted from the light-emitting element LEL may be polarized in a particular direction through the polarizing member POL. Accordingly, the nanostructures of the metalenses ML1, ML2 and ML3 may have a shape having an anisotropic refractive index (e.g., a rectangular column shape having different horizontal and vertical lengths), or a shape having an isotropic refractive index (e.g., a circular column shape).

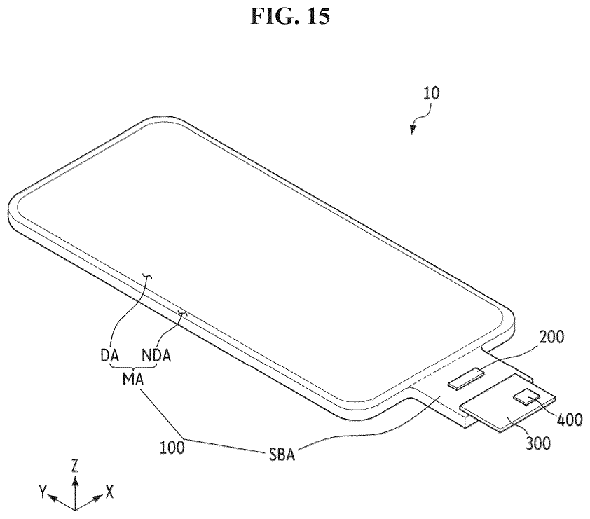

FIG. 15 is a perspective view of a display device according to some embodiments of the present disclosure. The following description will focus on differences and the redundant description may be omitted for economy of explanation.

Referring to FIG. 15, a display device 10 according to some embodiments of the present disclosure includes a display panel 100, a display driver circuit 200, a circuit board 300 and a touch driver circuit 400.

The display driver circuit 200 and the circuit board 300 may be identical to those described above with reference to FIG. 1.

The touch driver circuit 400 may be disposed on the circuit board 300. In an embodiment, the touch driver circuit 400 may be implemented as an integrated circuit (IC) and may be attached to the circuit board 300.

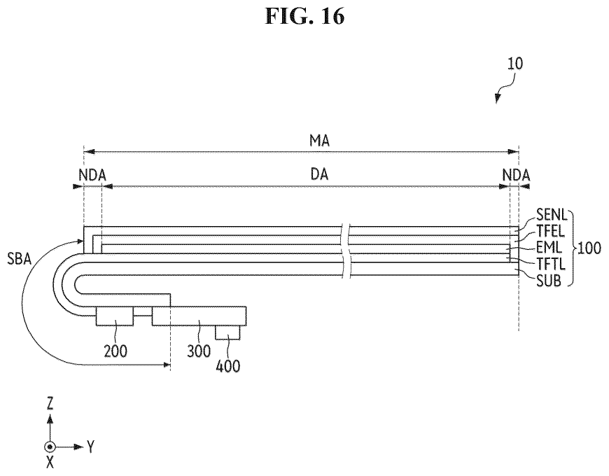

The touch driver circuit 400 may be electrically connected to the sensor electrodes of the touch sensing layer SENL (see FIG. 16) of the display panel 100. The touch driver circuit 400 may apply driving signals to the sensor electrodes of the touch sensing layer SENL and may measure mutual capacitances of the sensor electrodes. The driving signals may have driving pulses. The touch driver circuit 400 can determine whether a user has touched the display area DA or the presence of nearby object (e.g., hovering) based on the mutual capacitances. A user's touch refers to that an object such as the user's finger or a pen is brought into direct contact with a surface of the display device 10 disposed on the touch sensing layer SENL. The user's near proximity refers to that an object such as the user's finger or a pen is hovering over a surface of the display device 10.

FIG. 16 is a side view of the display device of FIG. 15. The following description will focus on differences and the redundant description may be omitted for economy of explanation.

Referring to FIG. 16, the display panel 100 according to some embodiments of the present disclosure includes a substrate SUB, a thin-film transistor layer TFTL, an light-emitting element layer EML, an encapsulation layer TFEL, and a touch sensing layer SENL.

The substrate SUB, the thin-film transistor layer TFTL, the light-emitting element layer EML and the encapsulation layer TFEL may be formed in the same manner as the substrate SUB, the thin-film transistor layer TFTL, the light-emitting element layer EML and the encapsulation layer TFE of the display panel 100 described above with reference to FIG. 3.

The touch sensing layer SENL may be disposed on (e.g., disposed directly thereon) the encapsulation layer TFEL. The touch sensing layer SENL may be disposed in the display area DA and the non-display area NDA of the main area MA. The touch sensing layer SENL may sense a touch of a person or an object using sensor electrodes.

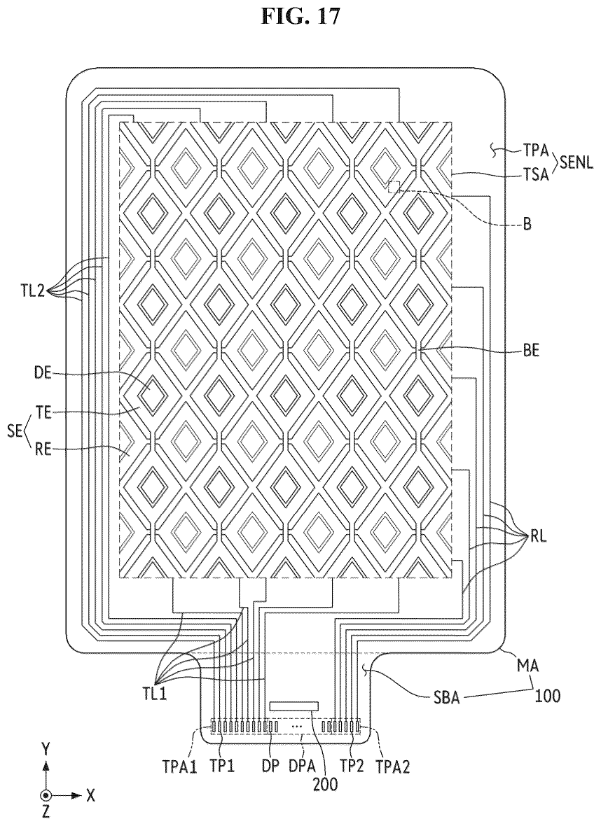

FIG. 17 is a layout view specifically showing the touch sensing layer of FIG. 16.

In the example shown in FIG. 17, the sensor electrodes SE of the touch sensing layer SENL include two kinds of electrodes, such as the driving electrodes TE and the sensing electrodes RE, the mutual capacitive sensing is carried out, such as driving signals are applied to the driving electrodes TE and then the voltages charged at the mutual capacitances can be sensed through the sensing electrodes RE. However, embodiments of the present disclosure are not necessarily limited thereto.

For convenience of illustration, FIG. 17 shows only the driving electrodes TE, the sensing electrodes RE, dummy patterns DE, sensor lines TL1, TL2 and RL, and sensor pads TP1 and TP2.

Referring to FIG. 17, in an embodiment, the touch sensing layer SENL includes a touch sensor area TSA for sensing a user's touch, and a touch peripheral area TPA disposed around the touch sensor area TSA (e.g., in a plan view). The touch sensor area TSA may overlap the display area DA of FIG. 15, and the touch peripheral area TPA may overlap the non-display area NDA of FIG. 15.

In an embodiment, the touch sensor area TSA includes the driving electrodes TE, the sensing electrodes RE and the dummy patterns DE. The driving electrodes TE and the sensing electrodes RE may be electrodes for forming mutual capacitance to sense a touch of an object or a person.

In an embodiment, the sensing electrodes RE may be arranged in the first direction (e.g., the X-axis direction) and second direction (e.g., the Y-axis direction). The sensing electrodes RE may be electrically connected to one another in the first direction (e.g., the X-axis direction). The sensing electrodes RE may be connected to one another in the first direction (e.g., the X-axis direction). The sensing electrodes RE adjacent to one another in the second direction (e.g., the Y-axis direction) may be electrically separated from one another.

The driving electrodes TE may be arranged in the first direction (e.g., the X-axis direction) and second direction (e.g., the Y-axis direction). The driving electrodes TE adjacent to one another in the first direction (e.g., the X-axis direction) may be electrically separated from one another. The driving electrodes TE may be electrically connected to one another in the second direction (e.g., the Y-axis direction). For example, the driving electrodes TE adjacent to one another in the second direction (e.g., the Y-axis direction) may be connected through bridge electrodes BE as shown in FIG. 17.

In an embodiment, each of the dummy patterns DE may be surrounded by the driving electrode TE or the sensing electrode RE (e.g., in a plan view). Each of the dummy patterns DE may be electrically separated from the driving electrode TE or the sensing electrode RE. Each of the dummy patterns DE may be spaced apart from the driving electrode TE or the sensing electrode RE. For example, each of the dummy patterns DE may be electrically floating.

In FIG. 17, the driving electrodes TE, the sensing electrodes RE and the dummy patterns DE each have a diamond shape when viewed from the top, but embodiments of the present disclosure are not necessarily limited thereto. For example, each of the driving electrodes TE, the sensing electrodes RE and the dummy patterns DE may have other quadrangular shape than a diamond shape, other polygonal shapes than a quadrangular shape, a circle shape or an ellipse shape when viewed from the top (e.g., in a plan view).

The sensor lines TL1, TL2 and RL may be disposed in the sensor peripheral area TPA. The sensor lines TL1, TL2 and RL include sensing lines RL connected to the sensing electrodes RE, and first driving lines TL1 and second driving lines TL2 connected to the driving electrodes TE.

The sensing electrodes RE disposed on one side of the touch sensor area TSA may be connected to the sensing lines RL, respectively. For example, some of the sensing electrodes RE electrically connected in the first direction (e.g., the X-axis direction) that are disposed at the right end may be connected to the sensing lines RL as shown in FIG. 17. The sensing lines RL may be connected to second sensor pads TP2, respectively. Thus, the touch driver circuit 400 may be electrically connected to the sensing electrodes RE.

The driving electrodes TE disposed on one side of the touch sensor area TSA may be connected to the first driving lines TL1, respectively, while the driving electrodes TE disposed on the other side of the touch sensor area TSA may be connected to the second driving lines TL2, respectively. For example, some of the driving electrodes TE electrically connected to one another in the second direction (e.g., the Y-axis direction) on the lowermost side may be connected to the first driving line TL1, while some of the driving electrodes TE disposed on the uppermost side may be connected to the second driving line TL2, as shown in FIG. 17. The second driving lines TL2 may be connected to the driving electrodes TE on the upper side of the touch sensor area TSA via the left outer side of the touch sensor area TSA.

The first driving lines TL1 and the second driving lines TL2 may be connected to the first sensor pads TP1, respectively. Thus, the touch driver circuit 400 may be electrically connected to the driving electrodes TE. The driving electrodes TE are connected to the driving lines TL1 and TL2 on both sides of the touch sensor area TSA, and receive the touch driving signals. Therefore, it is possible to prevent a difference between the touch driving signals applied to the driving electrodes TE disposed on the lower side of the touch sensor area TSA and the touch driving signals applied to the driving electrodes TE disposed on the upper side of the touch sensor area TSA which occurs due to the RC delay of the touch driving signals.

The first sensor pad area TPA1 in which the first sensor pads TP1 are disposed may be disposed on one side of the display pad area DPA in which the display pads DP are disposed. The second sensor pad area TPA2 in which the second sensor pads TP2 are disposed may be disposed on the other side of the display pad area DPA. The display pads DP may be electrically connected to data lines of the display panel 100.

The display pad area DPA, the first sensor pad area TPA1 and the second sensor pad area TPA2 may correspond to the pads of the display panel 100 connected to the circuit board 300 shown in FIG. 15. The circuit board 300 may be disposed on the display pads DP, the first sensor pads TP1, and the second sensor pads TP2. In an embodiment, the display pads DP, the first sensor pads TP1 and the second sensor pads TP2 may be electrically connected to the circuit board 300 using a low-resistance, high-reliability material such as an anisotropic conductive film or a SAP. Therefore, the display pads DP, the first sensor pads TP1 and the second sensor pads TP2 may be electrically connected to the touch driver circuit 400 disposed on the circuit board 300.

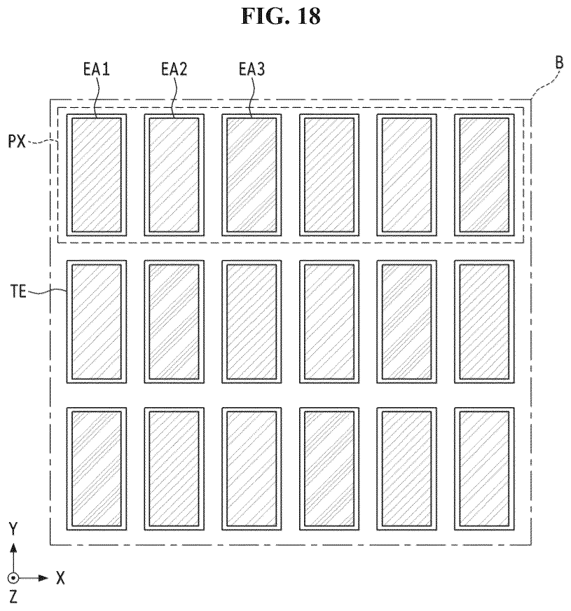

FIG. 18 is a layout diagram showing area B of FIG. 17 in detail. The following description will focus on differences and the redundant description may be omitted for economy of explanation.

The pixel PX and the light-emitting areas EA1 to EA3 may be formed in the same manner as the pixel PX and the light-emitting areas EA1 to EA3 of the display panel 100 described above with reference to FIG. 2.

Referring to FIG. 18, the driving electrodes TE may have a mesh structure or a net structure when viewed from the top (e.g., in a plan view). Accordingly, the driving electrodes TE may be spaced apart from the light-emitting areas EA1 to EA3 of each of the pixels PX (e.g., in the Y-axis direction). Therefore, it is possible to avoid the luminance of light from decreasing as the light output from the light-emitting areas EA1 to EA3 is covered by the driving electrodes TE.

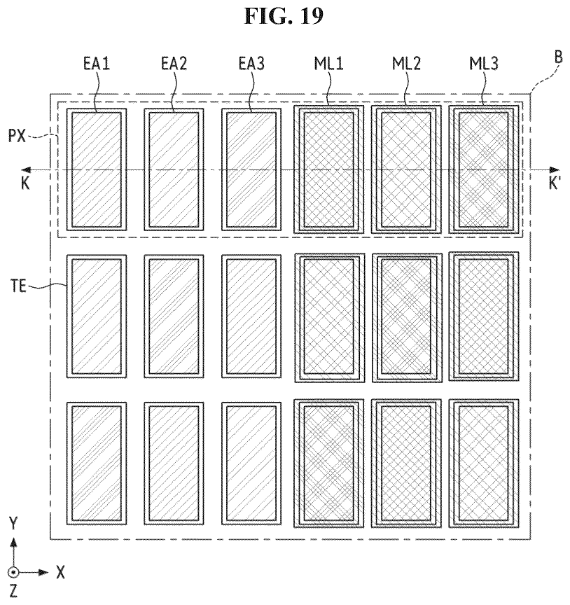

FIG. 19 is a layout diagram showing area B of FIG. 17 in detail. The following description will focus on differences and the redundant description may be omitted for economy of explanation.

Referring to FIG. 19, one of two first light-emitting areas EA1 of the pixel PX may overlap with the first metalens ML1 (e.g., in the Z-axis direction). The first metalens ML1 may cover the first light-emitting area EA1. In an embodiment, the shape of the first metalens ML1 may follow the shape of the first light-emitting area EA1 when viewed from the top (e.g., in a plan view). For example, the shape of the first metalens ML1 when viewed from the top may be, but is not necessarily limited to, a rectangle.

One of two second light-emitting areas EA2 of the pixel PX may overlap with the second metalens ML2 (e.g., in the Z-axis direction). The second metalens ML2 may cover the second light-emitting area EA2. In an embodiment, the shape of the second metalens ML2 may follow the shape of the second light-emitting area EA2 when viewed from the top. For example, the shape of the second metalens ML2 when viewed from the top may be, but is not necessarily limited to, a rectangle.

One of two third light-emitting areas EA3 of the pixel PX may overlap with the third metalens ML3 (e.g., in the Z-axis direction). The third metalens ML3 may cover the third light-emitting area EA3. The shape of the third metalens ML3 may follow the shape of the third light-emitting area EA3 when viewed from the top. For example, the shape of the third metalens ML3 when viewed from the top may be, but is not necessarily limited to, a rectangle.

In the example shown in FIG. 19, a first metalens ML1 overlaps with a first light-emitting area EA1, a second metalens ML2 overlaps with a second light-emitting area EA2, and a third metalens ML3 overlaps with a third light-emitting area EA3. However, according to some embodiments of the present disclosure, the first metalens ML1 may overlap with one of the first light-emitting areas EA1, one of the second light-emitting areas EA2 and one of the third light-emitting areas EA3, the second metalens ML2 may overlap with one of the first light-emitting areas EA1, one of the second light-emitting areas EA2 and one of the third light-emitting areas EA3, and the third metalens ML3 may overlap with one of the first light-emitting areas EA1, one of the second light-emitting areas EA2 and one of the third light-emitting areas EA3.

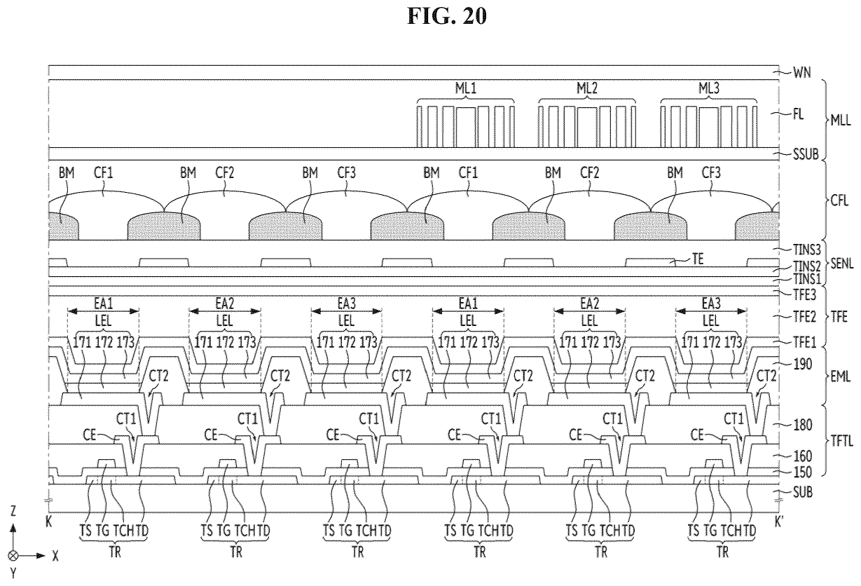

FIG. 20 is a cross-sectional view of the display device, taken along line K-K′ of FIG. 19. The following description will focus on differences and the redundant description may be omitted for economy of explanation.

Referring to FIG. 20, in an embodiment the display panel 100 may include a substrate SUB, a thin-film transistor layer TFTL, an light-emitting element layer EML, an encapsulation layer TFE, a touch sensing layer SENL, a color filter layer CFL, a metalens layer MLL, and a window member WN.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the touch sensing layer SENL may be disposed on the encapsulation layer TFE (e.g., disposed directly thereon in the Z-axis direction). The color filter layer CFL may be disposed on the touch sensing layer SENL (e.g., disposed directly thereon in the Z-axis direction), and the metalens layer MLL may be disposed on the color filter layer CFL (e.g., disposed directly thereon in the Z-axis direction). The window member WN may be disposed on the metalens layer MLL (e.g., disposed directly thereon in the Z-axis direction).

The detailed configurations of the substrate SUB, the thin-film transistor layer TFTL, the light-emitting element layer EML, the encapsulation layer TFE, the color filter layer CFL, the metalens layer MLL and the window member WN may be identical to those described above.

In an embodiment, the touch sensing layer SENL may include a first touch insulating film TINS1, a second touch insulating film TINS2, a third touch insulating film TINS3, and driving electrodes TE. In an embodiment, the touch sensing layer SENL may further include sensing electrodes RE and bridge electrodes BE.

The first touch insulating film TINS1 may be disposed on the encapsulation layer TFE (e.g., disposed directly thereon in the Z-axis direction). In an embodiment, the first touch insulating film TINS1 may be, but is not necessarily limited to, a silicon nitride layer, a silicon oxynitride layer, a silicon oxide layer, a titanium oxide layer, or an aluminum oxide layer.

In an embodiment, the bridge electrodes BE may be disposed on (e.g., disposed directly thereon) the first touch insulating film TINS1. In an embodiment, the bridge connection electrode BE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating film TINS2 may be disposed on (e.g., disposed directly thereon) the bridge electrodes BE and the first touch insulating film TINS1. In an embodiment, the second touch insulating film TINS2 may be formed of an inorganic layer, for example, a silicon nitride layer, a silicon oxynitride layer, a silicon oxide layer, a titanium oxide layer, or an aluminum oxide layer.

The driving electrodes TE may be disposed on the second touch insulating film TINS2 (e.g., disposed directly thereon in the Z-axis direction). The driving electrodes TE may be referred to as “touch electrodes”. In addition to the driving electrodes TE, the sensing electrodes RE, the dummy patterns DE, the first driving lines TL1, the second driving lines TL2 and the sensing lines RL shown in FIG. 17 may be disposed on (e.g., disposed directly thereon) the second touch insulating film TINS2.

The driving electrodes TE may overlap with the pixel-defining layer 190 of the light-emitting element layer EML in the third direction (e.g., the Z-axis direction). The driving electrodes TE may overlap with the black matrix BM of the color filter layer CFL in the third direction (e.g., the Z-axis direction). The driving electrodes TE may or may not overlap with the metalenses ML1 to ML3 in the third direction (e.g., the Z-axis direction). For example, in an embodiment shown in FIG. 20 the edges of the metalenses ML1 to ML3 may overlap with edges of the driving electrodes TE (e.g., in the Z-axis direction). However, in some embodiments, the metalenses ML1 to ML3 may not have any overlap with the driving electrodes TE (e.g., in the Z-axis direction). The third touch insulating layer TINS3 may be disposed on (e.g., disposed directly on) the driving electrodes TE and the second touch insulating layer TINS2.

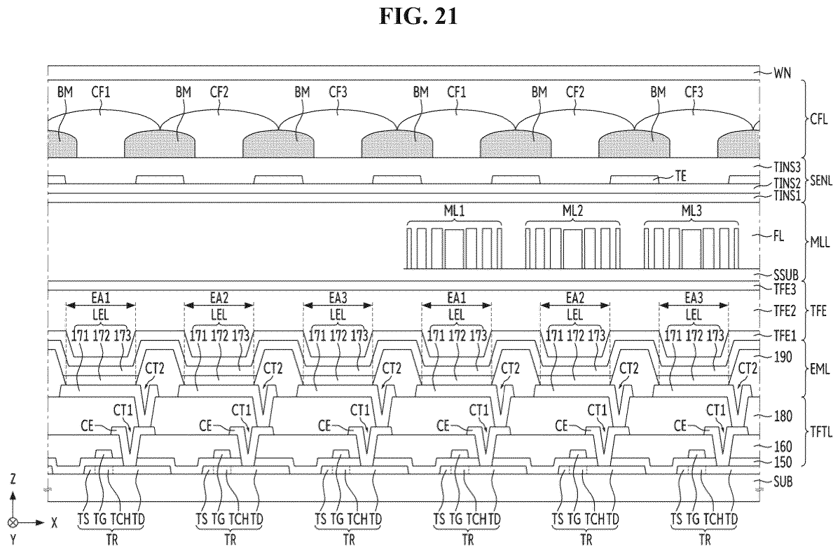

FIG. 21 is a cross-sectional view of the display device, taken along line K-K′ of FIG. 19. The following description will focus on differences and the redundant description may be omitted for economy of explanation.

Referring to FIG. 21, in an embodiment the display panel 100 may include a substrate SUB, a thin-film transistor layer TFTL, a light-emitting element layer EML, an encapsulation layer TFE, a metalens layer MLL, a touch sensing layer SENL, a color filter layer CFL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the metalens layer MLL may be disposed on the encapsulation layer TFE (e.g., disposed directly thereon in the Z-axis direction). The touch sensing layer SENL may be disposed on the metalens layer MLL (e.g., disposed directly thereon in the Z-axis direction), and the color filter layer CFL may be disposed on the touch sensing layer SENL (e.g., disposed directly thereon in the Z-axis direction). The window member WN may be disposed on the color filter layer CFL (e.g., disposed directly thereon in the Z-axis direction).

Compared to FIG. 20, the metalens layer MLL that was disposed on the color filter layer CFL in FIG. 20 may be disposed on the encapsulation layer TFE in FIG. 21. The touch sensing layer SENL and the color filter layer CFL may be disposed on the metalens layer MLL.

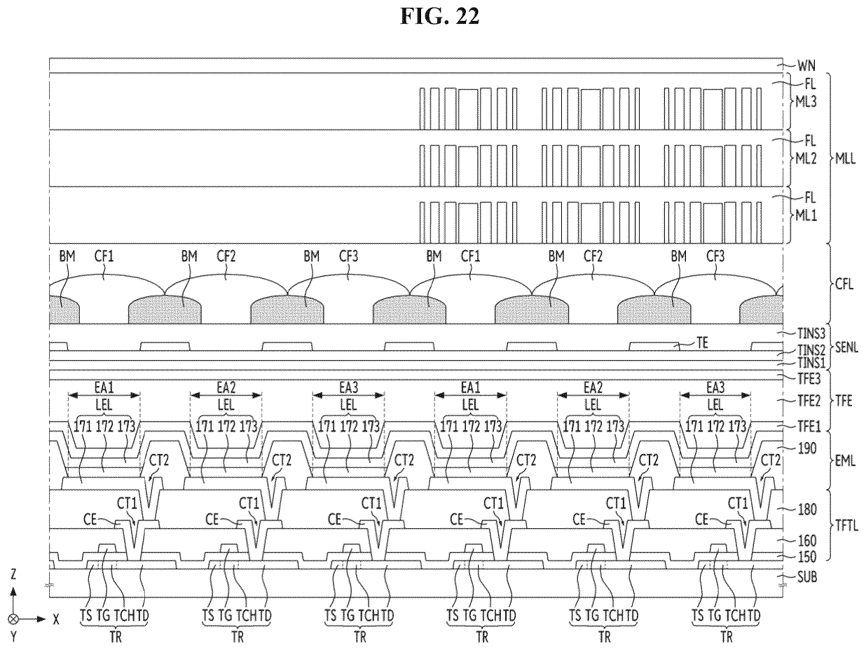

FIG. 22 is a cross-sectional view of the display device, taken along line K-K′ of FIG. 19. The following description will focus on differences and the redundant description may be omitted for economy of explanation.

Referring to FIG. 22, in an embodiment the display panel 100 may include a substrate SUB, a thin-film transistor layer TFTL, an light-emitting element layer EML, an encapsulation layer TFE, a touch sensing layer SENL, a color filter layer CFL, a metalens layer MLL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the touch sensing layer SENL may be disposed on the encapsulation layer TFE (e.g., disposed directly thereon in the Z-axis direction). The color filter layer CFL may be disposed on the touch sensing layer SENL (e.g., disposed directly thereon in the Z-axis direction), and the metalens layer MLL may be disposed on the color filter layer CFL (e.g., disposed directly thereon in the Z-axis direction). The window member WN may be disposed on the metalens layer MLL (e.g., disposed directly thereon in the Z-axis direction).

In an embodiment, the metalens layer MLL may include a first metalens ML1, a second metalens ML2, and a third metalens ML3 (e.g., consecutively stacked in the Z-axis direction).

The first metalens ML1 may overlap with one of two first light-emitting areas EA1, one of two second light-emitting areas EA2 and one of two third light-emitting areas EA3 of the pixel PX (e.g., in the Z-axis direction).

The first metalens ML1 may include a fourth nanostructure having a fourth spacing, a fourth width, and a fourth height. The first metalens ML1 may refract light of the first color.

The second metalens ML2 may overlap with one of two first light-emitting areas EA1, one of two second light-emitting areas EA2, and one of two third light-emitting areas EA3 (e.g., in the Z-axis direction) of the pixel PX.

The second metalens ML2 may include a fifth nanostructure having a fifth spacing, a fifth width, and a fifth height. The second metalens ML2 may refract light of the second color.

The third metalens ML3 may overlap with one of two first light-emitting areas EA1, one of two second light-emitting areas EA2, and one of two third light-emitting areas EA3 (e.g., in the Z-axis direction) of the pixel PX.

The third metalens ML3 may include a sixth nanostructure having a sixth spacing, a sixth width, and a sixth height. The third metalens ML3 may refract light of the third color.

The fourth to sixth nanostructures may be different from one another. Accordingly, each of the first to third metalenses ML1 to ML3 may refract light of different wavelength ranges from each other.

The first metalens ML1, the second metalens ML2 and the third metalens ML3 may overlap with one another in the third direction (e.g., the Z-axis direction). In the example shown in FIG. 22, the second metalens ML2 is disposed on the first metalens ML1 (e.g., disposed directly thereon in the Z-axis direction), and the third metalens ML3 is disposed on the second metalens ML2 (e.g., disposed directly thereon in the Z-axis direction). It should be understood, however, that embodiments of the present disclosure are not necessarily limited thereto.

The first metalens ML1 may refract light of the first color. Accordingly, the light of the second color output from the second light-emitting area EA2 and the light of the third color output from the third light-emitting area EA3 may pass through the first metalens ML1 without being refracted.

The second metalens ML2 may refract light of the second color. Accordingly, the light of the first color output from the first light-emitting area EA1 and the light of the third color output from the third light-emitting area EA3 may pass through the second metalens ML2 without being refracted.

The third metalens ML3 may refract light of the third color. Accordingly, the light of the first color output from the first light-emitting area EA1 and the light of the second color output from the second light-emitting area EA2 may pass through the third metalens ML3 without being refracted.

Light of the first color output from a first light-emitting area EA1 may sequentially pass through the encapsulation layer TFE, the touch sensing layer SENL, and the first color filter CF1. After having passed through the first color filter CF1, the light of the first color may be refracted at the first metalens ML1, and may pass through the second metalens ML2 and the third metalens ML3 without being refracted.

Light of the second color output from a second light-emitting area EA2 may sequentially pass through the encapsulation layer TFE, the touch sensing layer SENL, and the second color filter CF2. After having passed through the second color filter CF2, the light of the second color may pass through the first metalens ML1 without being refracted, may be refracted at the second metalens ML2, and may pass through the third metalens ML3 without being refracted.

Light of the third color output from a third light-emitting area EA3 may sequentially pass through the encapsulation layer TFE, the touch sensing layer SENL, and the third color filter CF3. After having passed through the third color filter CF3, the light of the third color may pass through the first metalens ML1 and the second metalens ML2 without being refracted and may be refracted at the third metalens ML3.

According to this embodiment, it is possible to simplify the process of aligning the metalenses ML1 to ML3 with the light-emitting areas EA1 to EA3 by sequentially forming the first metalens ML1, the second metalens ML2 and the third metalens ML3 (e.g., in the Z-axis direction). By doing so, it is possible to reduce the difficulty of the process.

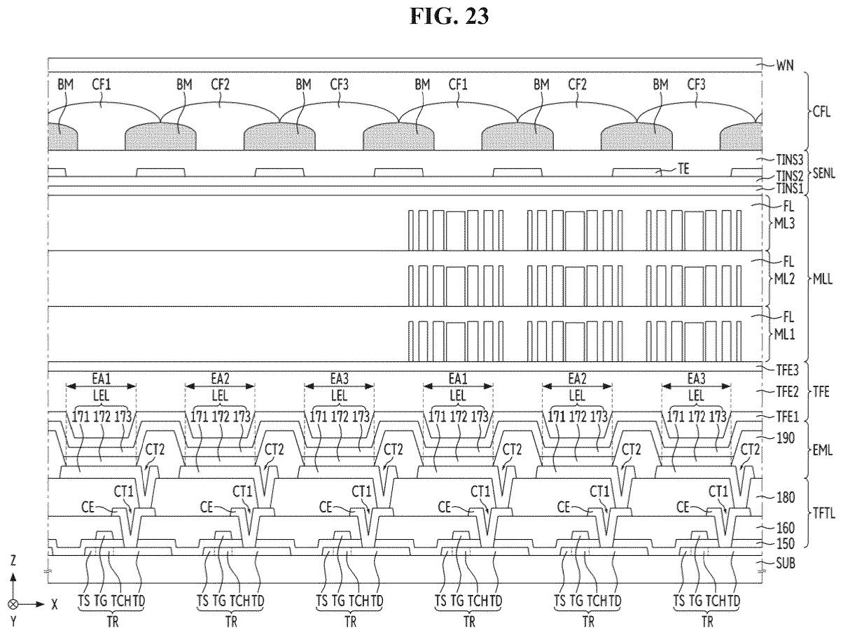

FIG. 23 is a cross-sectional view of the display device, taken along line K-K′ of FIG. 19. The following description will focus on differences and the redundant description may be omitted for economy of explanation.

Referring to FIG. 23, in an embodiment the display panel 100 may include a substrate SUB, a thin-film transistor layer TFTL, an light-emitting element layer EML, an encapsulation layer TFE, a metalens layer MLL, a touch sensing layer SENL, a color filter layer CFL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the metalens layer MLL may be disposed on the encapsulation layer TFE (e.g., disposed directly thereon in the Z-axis direction). The touch sensing layer SENL may be disposed on the metalens layer MLL (e.g., disposed directly thereon in the Z-axis direction), and the color filter layer CFL may be disposed on the touch sensing layer SENL (e.g., disposed directly thereon in the Z-axis direction). The window member WN may be disposed on the color filter layer CFL (e.g., disposed directly thereon in the Z-axis direction).

In an embodiment, the metalens layer MLL may have a structure in which the first metalens ML1, the second metalens ML2 and the third metalens ML3 are stacked on one another in the third direction (e.g., the Z-axis direction). The first to third metalenses ML1 to ML3 may overlap one another in the third direction (e.g., the Z-axis direction). The first to third metalenses ML1 to ML3 may overlap with one of the first light-emitting areas EA1, one of the second light-emitting areas EA2, and one of the third light-emitting areas EA3. One first light-emitting area EA1, one second light-emitting area EA2 and one third light-emitting area EA3 may emit light during a 3D image display period.

Compared to FIG. 22, the metalens layer MLL that was disposed on the color filter layer CFL in FIG. 22 may be disposed on the encapsulation layer TFE in FIG. 23 (e.g., disposed directly thereon in the Z-axis direction).

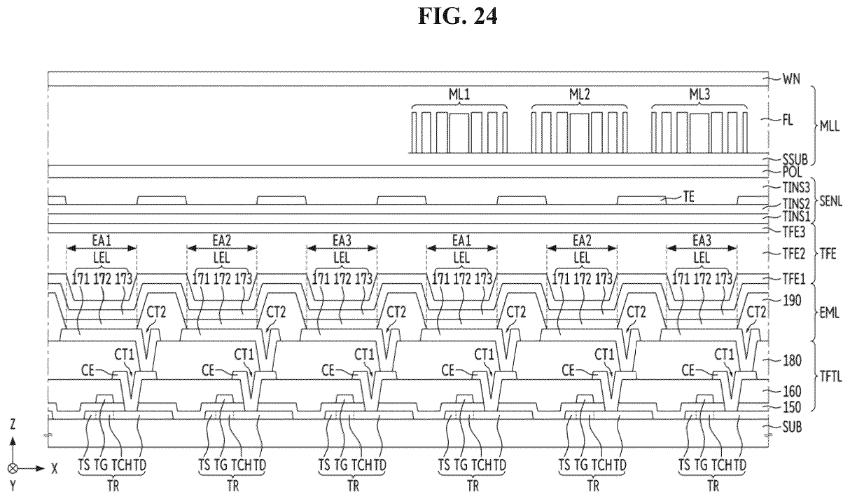

FIG. 24 is a cross-sectional view of the display device, taken along line K-K′ of FIG. 19. The following description will focus on differences and the redundant description may be omitted for economy of explanation.

Referring to FIG. 24, in an embodiment the display panel 100 may include a substrate SUB, a thin-film transistor layer TFTL, an light-emitting element layer EML, an encapsulation layer TFE, a touch sensing layer SENL, a polarizing member POL, a metalens layer MLL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the touch sensing layer SENL may be disposed on the encapsulation layer TFE (e.g., disposed directly thereon in the Z-axis direction). The polarizing member POL may be disposed on the touch sensing layer SENL (e.g., disposed directly thereon in the Z-axis direction), and the metalens layer MLL may be disposed on the polarizing member POL (e.g., disposed directly thereon in the Z-axis direction). The window member WN may be disposed on the metalens layer MLL (e.g., disposed directly thereon in the Z-axis direction).

Compared to FIG. 20, the display panel 100 in FIG. 24 may include a polarizing member POL instead of the color filter layer CFL of FIG. 20. The polarizing member POL can suppress reflection of light incident on the display panel 100 from the outside (e.g., the external environment).

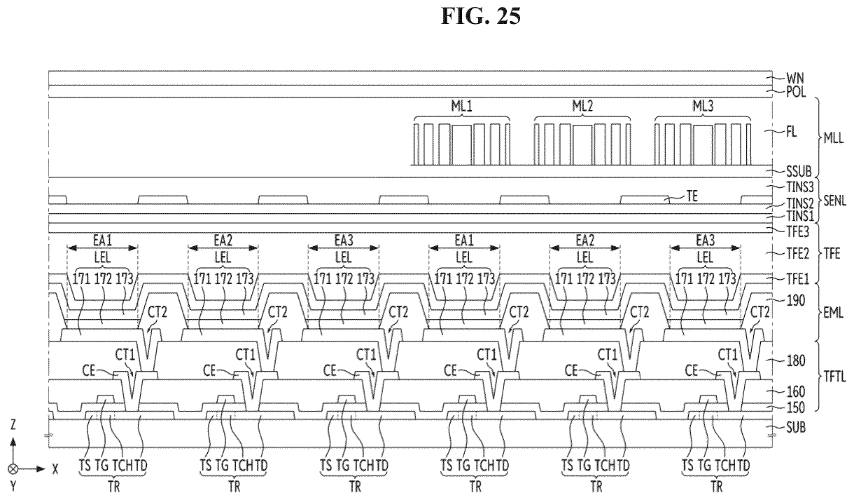

FIG. 25 is a cross-sectional view of the display device, taken along line K-K′ of FIG. 19. The following description will focus on differences and the redundant description may be omitted for economy of explanation.

Referring to FIG. 25, in an embodiment the display panel 100 may include a substrate SUB, a thin-film transistor layer TFTL, an light-emitting element layer EML, an encapsulation layer TFE, a touch sensing layer SENL, a metalens layer MLL, a polarizing member POL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the touch sensing layer SENL may be disposed on the encapsulation layer TFE (e.g., disposed directly thereon in the Z-axis direction). The metalens layer MLL may be disposed on the touch sensing layer SENL (e.g., disposed directly thereon in the Z-axis direction), and the polarizing member POL may be disposed on the metalens layer MLL (e.g., disposed directly thereon in the Z-axis direction). The window member WN may be disposed on the polarizing member POL (e.g., disposed directly thereon in the Z-axis direction).

Compared to FIG. 24, the positions of the polarizing member POL and the metalens layer MLL may be switched in the vertical direction (e.g., the Z-axis direction). In this manner, the polarizing member POL can effectively reduce the reflection of light incident on the display panel 100 from the outside (e.g., the external environment).

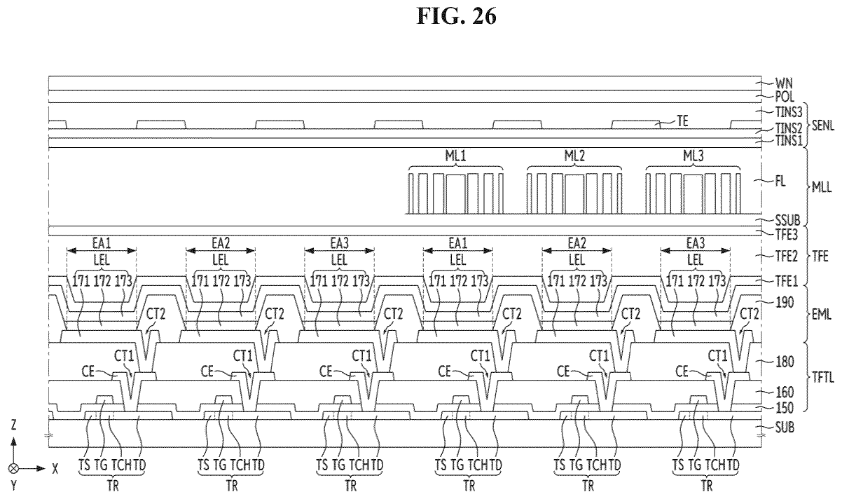

FIG. 26 is a cross-sectional view of the display device, taken along line K-K′ of FIG. 19. The following description will focus on differences and the redundant description may be omitted for economy of explanation.

Referring to FIG. 26, in an embodiment the display panel 100 may include a substrate SUB, a thin-film transistor layer TFTL, an light-emitting element layer EML, an encapsulation layer TFE, a metalens layer MLL, a touch sensing layer SENL, a polarizing member POL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the metalens layer MLL may be disposed on the encapsulation layer TFE (e.g., disposed directly thereon in the Z-axis direction). The touch sensing layer SENL may be disposed on the metalens layer MLL (e.g., disposed directly thereon in the Z-axis direction), and the polarizing member POL may be disposed on the touch sensing layer SENL (e.g., disposed directly thereon in the Z-axis direction). In this embodiment, the polarizing member POL is spaced apart from the metalens layer MLL and does not directly contact a surface of the metalens layer MLL. The window member WN may be disposed on the polarizing member POL (e.g., disposed directly thereon in the Z-axis direction).

Compared to FIG. 25, the positions of the metalens layer MLL and the touch sensing layer SENL may be switched in the vertical direction (e.g., the Z-axis direction). Since the touch sensing layer SENL is disposed on other layers of the display panel 100, touch sensitivity can be increased according to this embodiment.

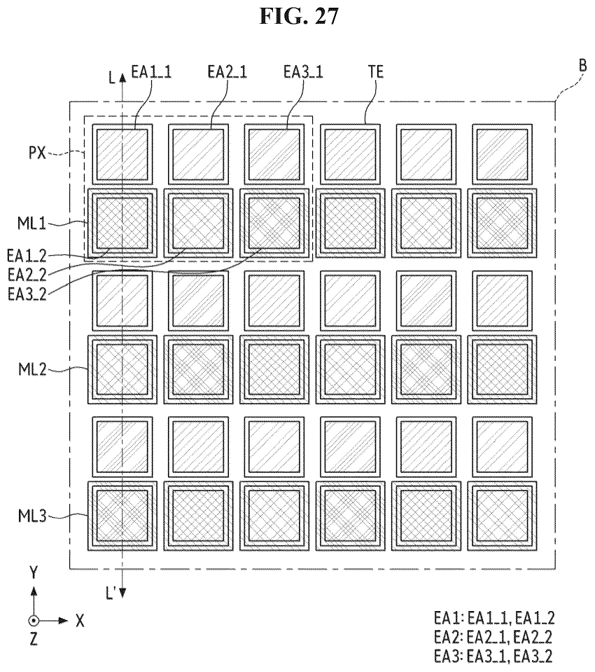

FIG. 27 is a layout diagram showing area B of FIG. 17 in detail. The following description will focus on differences and the redundant description may be omitted for economy of explanation.

Referring to FIG. 27, in an embodiment a pixel PX may include a first light-emitting area EA1, a second light-emitting area EA2, and a third light-emitting area EA3.

In an embodiment, the first light-emitting area EA1 may include a plurality of first subsidiary light-emitting areas EA1_1 and EA1_2. The second light-emitting area EA2 may include a plurality of second subsidiary light-emitting areas EA2_1 and EA2_2. The third light-emitting area EA3 may include a plurality of third subsidiary light-emitting areas EA3_1 and EA3_2.

In a single pixel PX, a plurality of first subsidiary light-emitting areas EA1_1 and EA1_2 may be adjacent to each other (e.g., directly adjacent to each other in the Y-axis direction). In a single pixel PX, a plurality of second subsidiary light-emitting areas EA2_1 and EA2_2 may be adjacent to each other (e.g., directly adjacent to each other in the Y-axis direction). In a single pixel PX, a plurality of third subsidiary light-emitting areas EA3_1 and EA3_2 may be adjacent to each other. In the example shown in FIG. 27, two first subsidiary light-emitting areas EA1_1 and EA1_2 are adjacent to each other in the second direction (e.g., the Y-axis direction), two second subsidiary light-emitting areas EA2_1 and EA2_2 are adjacent to each other in the second direction (e.g., the Y-axis direction), and two third subsidiary light-emitting areas EA3_1 and EA3_2 are adjacent to each other in the second direction (e.g., the Y-axis direction). It should be understood, however, that embodiments of the present disclosure are not necessarily limited thereto.

In a single pixel PX, one first subsidiary light-emitting area EA1_1 of the two first subsidiary light-emitting areas EA1_1 and EA1_2 may operate in a 2D image display period, while the other first subsidiary light-emitting area EA1_2 may operate in a 3D image display period. In a single pixel PX, one second subsidiary light-emitting area EA2_1 of the two second subsidiary light-emitting areas EA2_1 and EA2_2 may operate in a 2D image display period, while the other second subsidiary light-emitting area EA2_2 may operate in a 3D image display period. In a single pixel PX, one third subsidiary light-emitting area EA3_1 of the two third subsidiary light-emitting areas EA3_1 and EA3_2 may operate in a 2D image display period, while the other third subsidiary light-emitting area EA3_2 may operate in a 3D image display period. In this manner, it is possible to prevent degradation of resolution occurring during the 2D image display period and the 3D image display period.

Another first subsidiary light-emitting area EA1_2 may overlap with the first metalens ML1 (e.g., in the Z-axis direction), another second subsidiary light-emitting area EA2_2 may overlap with the second metalens ML2 (e.g., in the Z-axis direction), and another third subsidiary light-emitting area EA3_2 may overlap with the third metalens ML3 (e.g., in the Z-axis direction).

In the example shown in FIG. 27, the first metalens ML1 overlaps with another first subsidiary light-emitting area EA1_2 (e.g., in the Z-axis direction), the second metalens ML2 overlaps with another second subsidiary light-emitting area EA2_2 (e.g., in the Z-axis direction), and the third metalens ML3 overlaps with another third subsidiary light-emitting area EA3_2 (e.g., in the Z-axis direction). In some embodiments of the present disclosure, the first metalens ML1 may overlap with another first subsidiary light-emitting area EA1_2, another second subsidiary light-emitting area EA2_2 and another third subsidiary light-emitting area EA3_2, the second metalens ML2 may overlap with another first subsidiary light-emitting area EA1_2, another second subsidiary light-emitting area EA2_2 and another third subsidiary light-emitting area EA3_2, and the third metalens ML3 may overlap with another first subsidiary light-emitting area EA1_2, another second subsidiary light-emitting area EA2_2 and another third subsidiary light-emitting area EA3_2.

The driving electrodes TE may have a mesh structure or a net structure when viewed from the top (e.g., in a plan view). Accordingly, the driving electrodes TE may be spaced apart from the light-emitting areas EA1 to EA3 of each of the pixels PX.

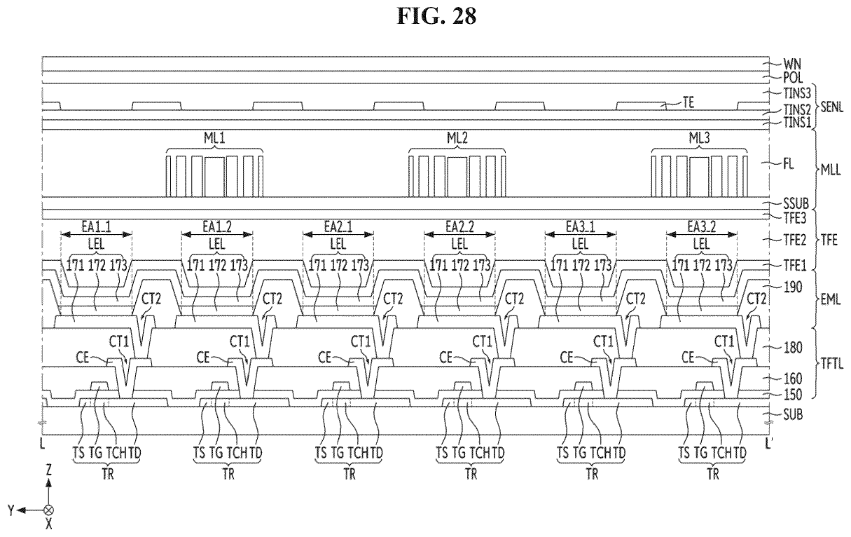

FIG. 28 is a cross-sectional view of the display device, taken along line L-L′ of FIG. 27. The following description will focus on differences and the redundant description may be omitted for economy of explanation.

Referring to FIG. 28, in an embodiment the display panel 100 may include a substrate SUB, a thin-film transistor layer TFTL, a light-emitting element layer EML, an encapsulation layer TFE, a metalens layer MLL, a touch sensing layer SENL, a polarizing member POL, and a window member WN disposed on the substrate SUB.

Compared to FIG. 26, the first metalens ML1, the second metalens ML2 and the third metalens ML3 may be spaced apart from one another in the second direction (e.g., the Y-axis direction). A second subsidiary light-emitting area EA2_1 may be disposed between the first metalens ML1 and the second metalens ML2 (e.g., in the Y-axis direction). A third subsidiary light-emitting area EA3_1 may be disposed between the second metalens ML2 and the third metalens ML3 (e.g., in the Y-axis direction).

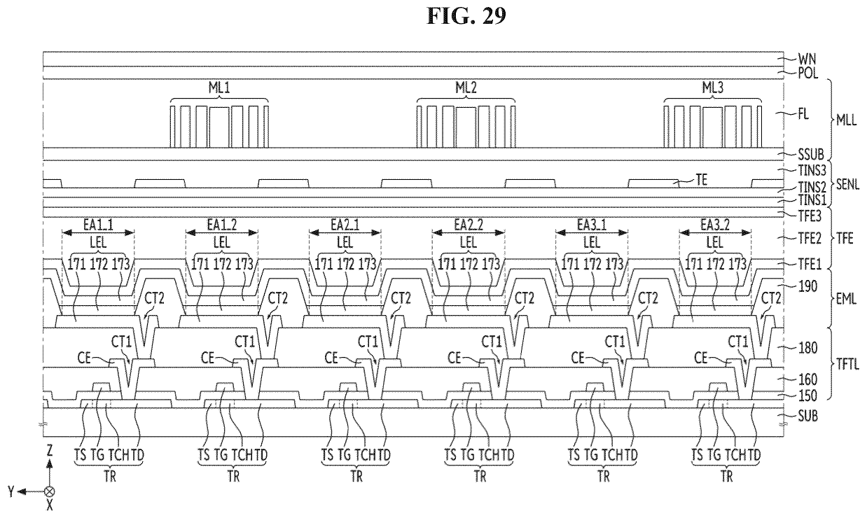

FIG. 29 is a cross-sectional view of the display device, taken along line L-L′ of FIG. 27. The following description will focus on differences and the redundant description may be omitted for economy of explanation.

Referring to FIG. 29, in an embodiment the display panel 100 may include a substrate SUB, a thin-film transistor layer TFTL disposed on the substrate SUB, an light-emitting element layer EML, an encapsulation layer TFE, a touch sensing layer SENL, a metalens layer MLL, a polarizing member POL, and a window member WN.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the touch sensing layer SENL may be disposed on the encapsulation layer TFE (e.g., disposed directly thereon in the Z-axis direction). The metalens layer MLL may be disposed on the touch sensing layer SENL (e.g., disposed directly thereon in the Z-axis direction), and the polarizing member POL may be disposed on the metalens layer MLL (e.g., disposed directly thereon in the Z-axis direction). The window member WN may be disposed on the polarizing member POL (e.g., disposed directly thereon in the Z-axis direction).

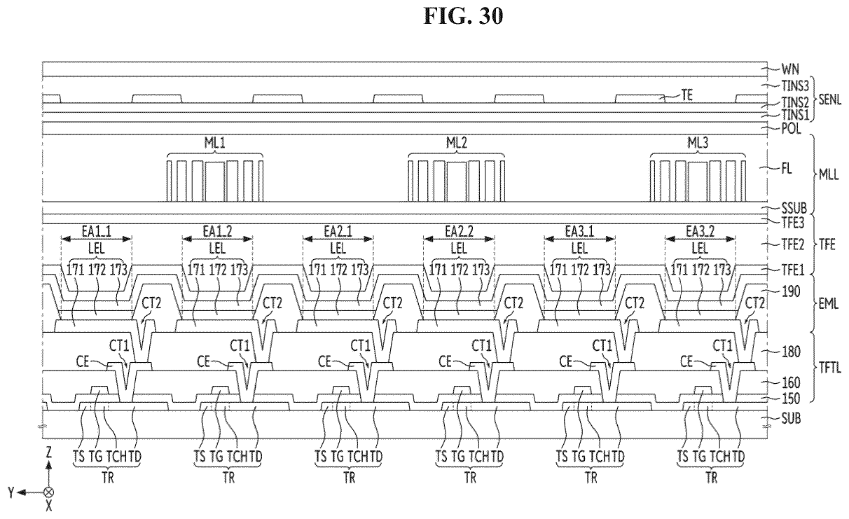

Compared to FIG. 28, the positions of the metalens layer MLL and the touch sensing layer SENL may be switched in the vertical direction in FIG. 30 (e.g., in the Z-axis direction).

FIG. 30 is a cross-sectional view of the display device, taken along line L-L′ of FIG. 27. The following description will focus on differences and the redundant description may be omitted for economy of explanation.

Referring to FIG. 30, in an embodiment the display panel 100 may include a substrate SUB, a thin-film transistor layer TFTL, an light-emitting element layer EML, an encapsulation layer TFE, a metalens layer MLL, a polarizing member POL, a touch sensing layer SENL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the metalens layer MLL may be disposed on the encapsulation layer TFE (e.g., disposed directly thereon in the Z-axis direction). The polarizing member POL may be disposed on the metalens layer MLL (e.g., disposed directly thereon in the Z-axis direction), and the touch sensing layer SENL may be disposed on the polarizing member POL (e.g., disposed directly thereon in the Z-axis direction). The window member WN may be disposed on the touch sensing layer SENL (e.g., disposed directly thereon in the Z-axis direction).

Compared to FIG. 29, the metalens layer MLL that was disposed between the touch sensing layer SENL and the polarizing member POL in FIG. 29 may be disposed on the encapsulation layer TFE in FIG. 30. In this manner, the touch sensing layer SENL may be disposed on other layers of the display panel 100, thereby increasing the touch sensitivity.

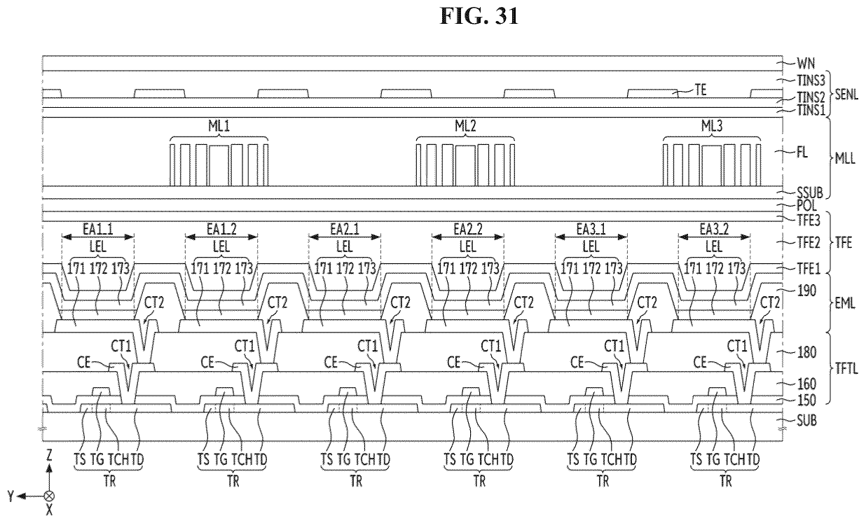

FIG. 31 is a cross-sectional view of the display device, taken along line L-L′ of FIG. 27. The following description will focus on differences and the redundant description may be omitted for economy of explanation.

Referring to FIG. 31, in an embodiment the display panel 100 may include a substrate SUB, a thin-film transistor layer TFTL, an light-emitting element layer EML, an encapsulation layer TFE, a polarizing member POL, a metalens layer MLL, a touch sensing layer SENL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the polarizing member POL may be disposed on the encapsulation layer TFE (e.g., disposed directly thereon in the Z-axis direction). The metalens layer MLL may be disposed on the polarizing member POL (e.g., disposed directly thereon in the Z-axis direction), and the touch sensing layer SENL may be disposed on the metalens layer MLL (e.g., disposed directly thereon in the Z-axis direction). The window member WN may be disposed on the touch sensing layer SENL (e.g., disposed directly thereon in the Z-axis direction).

Compared to FIG. 30, the polarizing member POL that was disposed between the metalens layer MLL and the touch sensing layer SENL may be disposed between the encapsulation layer TFE and the metalens layer MLL (e.g., in the Z-axis direction) in FIG. 31. As the metalens layer MLL is disposed on the polarizing member POL, the nanostructures of the metalenses ML1, ML2 and ML3 may have a shape having an anisotropic refractive index (e.g., a rectangular column shape having different horizontal and vertical lengths), or a shape having an isotropic refractive index (e.g., a circular column shape).

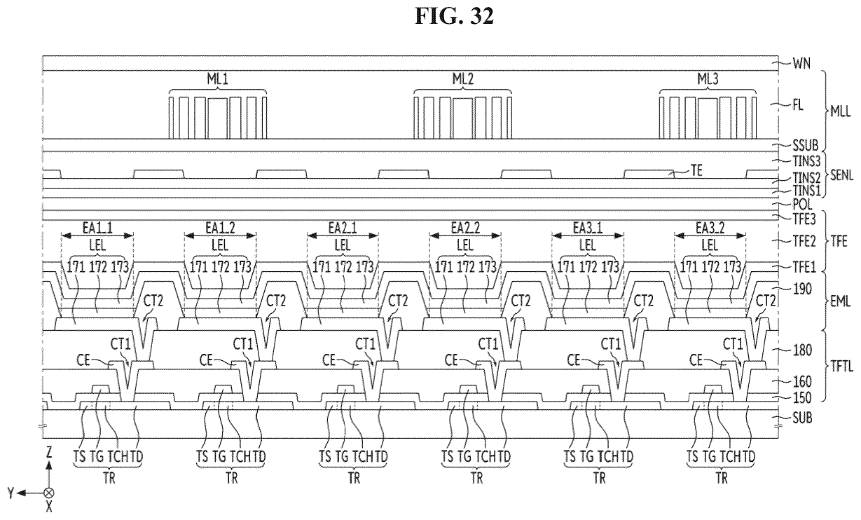

FIG. 32 is a cross-sectional view of the display device, taken along line L-L′ of FIG. 27. The following description will focus on differences and the redundant description may be omitted for economy of explanation.

Referring to FIG. 32, in an embodiment the display panel 100 may include a substrate SUB, a thin-film transistor layer TFTL, an light-emitting element layer EML, an encapsulation layer TFE, a polarizing member POL, a touch sensing layer SENL, a metalens layer MLL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the polarizing member POL may be disposed on the encapsulation layer TFE (e.g., disposed directly thereon in the Z-axis direction). The touch sensing layer SENL may be disposed on the polarizing member POL (e.g., disposed directly thereon in the Z-axis direction), and the metalens layer MLL may be disposed on the touch sensing layer SENL (e.g., disposed directly thereon in the Z-axis direction). The window member WN may be disposed on the metalens layer MLL (e.g., disposed directly thereon in the Z-axis direction).

Compared to FIG. 31, the positions of the metalens layer MLL and the touch sensing layer SENL may be switched in the vertical direction (e.g., in the Z-axis direction).

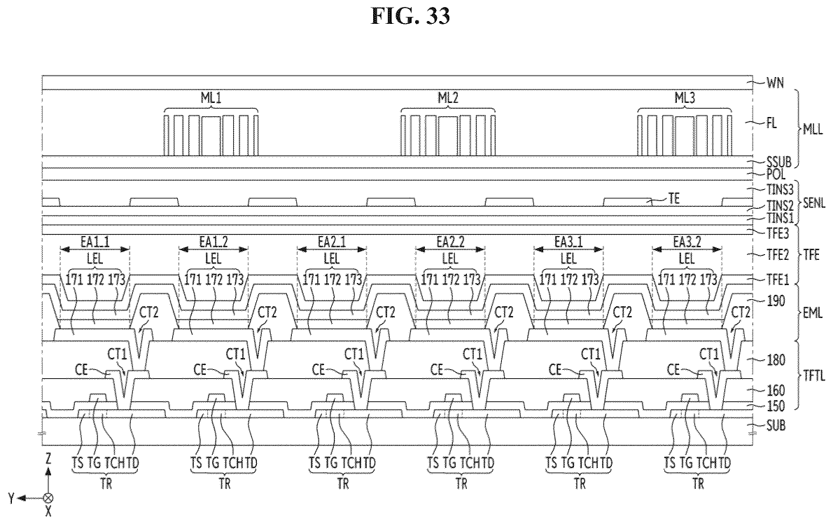

FIG. 33 is a cross-sectional view of the display device, taken along line L-L′ of FIG. 27. The following description will focus on differences and the redundant description may be omitted for economy of explanation.

Referring to FIG. 33, in an embodiment the display panel 100 may include a substrate SUB, a thin-film transistor layer TFTL, an light-emitting element layer EML, an encapsulation layer TFE, a touch sensing layer SENL, a polarizing member POL, a metalens layer MLL, and a window member WN disposed on the substrate SUB.

The thin-film transistor layer TFTL may be disposed on the substrate SUB (e.g., disposed directly thereon in the Z-axis direction), and the light-emitting element layer EML may be disposed on the thin-film transistor layer TFTL (e.g., disposed directly thereon in the Z-axis direction). The encapsulation layer TFE may be disposed on the light-emitting element layer EML (e.g., disposed directly thereon in the Z-axis direction), and the touch sensing layer SENL may be disposed on the encapsulation layer TFE (e.g., disposed directly thereon in the Z-axis direction). The polarizing member POL may be disposed on the touch sensing layer SENL (e.g., disposed directly thereon in the Z-axis direction), and the metalens layer MLL may be disposed on the polarizing member POL (e.g., disposed directly thereon in the Z-axis direction). The window member WN may be disposed on the metalens layer MLL (e.g., disposed directly thereon in the Z-axis direction).

Compared to FIG. 32, the polarizing member POL that was disposed on the encapsulation layer TFE in FIG. 21 may be disposed between the touch sensing layer SENL and the metalens layer MLL in FIG. 33 (e.g., in the Z-axis direction).

### The Electronic Device

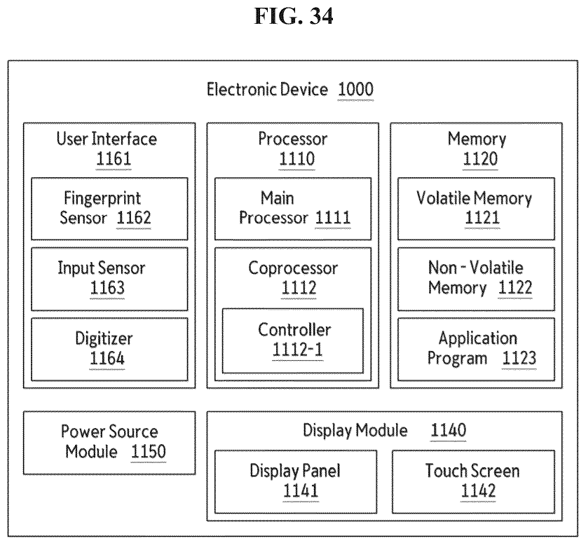

FIG. 34 is a diagram illustrating an electronic device according to an embodiment of the present invention. Referring to FIG. 34, the electronic device 1000 according to one embodiment of the present invention may output various information (e.g., images, text, music, etc.) through a display module 1140, which, for example, may correspond to the display device 10 shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 is an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device 10 shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer 1164 may detect an input by a passive pen or transmit and receive data with an active pen or a remote.

At least one of the fingerprint sensor 1162, the input sensor 1163, and the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device 10 shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although non-limiting embodiments of the present disclosure have been described with reference to the accompanying drawings, those skilled in the art would understand that various modifications and alterations may be made without departing from the technical idea or essential features of the present disclosure. Therefore, it should be understood that the above-mentioned embodiments are not limiting but illustrative in all aspects.

What is claimed is:

1. A display device comprising:
a substrate;
a plurality of light-emitting areas comprising a plurality of light-emitting elements arranged on the substrate;
a pixel-defining layer defining the plurality of light-emitting areas;
an encapsulation layer disposed on the plurality of light-emitting elements and the pixel-defining layer; and
a metalens layer disposed on the encapsulation layer and comprising a plurality of metalenses,
wherein the plurality of metalenses overlaps with some of the plurality of light-emitting areas in a thickness direction of the substrate.

2. The display device of claim 1, wherein the plurality of metalenses does not overlap with some others of the plurality of light-emitting areas in the thickness direction of the substrate.

3. The display device of claim 1, wherein:
the plurality of light-emitting areas comprises:
a plurality of first light-emitting areas emitting light of a first color, a plurality of second light-emitting areas emitting light of a second color, and a plurality of third light-emitting areas emitting light of a third color,
wherein the first to third colors are different from each other.

4. The display device of claim 3, wherein the plurality of metalenses comprises:
a first metalens overlapping with one of the plurality of first light-emitting areas in the thickness direction of the substrate and refracting light of the first color;
a second metalens overlapping with one of the plurality of second light-emitting areas in the thickness direction of the substrate and refracting light of the second color; and
a third metalens overlapping with one of the plurality of third light-emitting areas in the thickness direction of the substrate and refracting light of the third color.

5. The display device of claim 4, wherein:
the first metalens comprises first nanostructures having a first spacing, a first width and a first height; and
the second metalens comprises second nanostructures having a second spacing, a second width and a second height,
wherein the first nanostructures have a different nanostructure than the second nanostructures.

6. The display device of claim 5, wherein the third metalens comprises third nanostructures having a third gap, a third width and a third height,
wherein the third nanostructures have a different nanostructure than the first nanostructures and the second nanostructures.

7. The display device of claim 3, wherein the plurality of metalenses comprises a first metalens, a second metalens and a third metalens overlapping in the thickness direction of the substrate with one of the plurality of first light-emitting areas, one of the plurality of second light-emitting areas and one of the plurality of third light-emitting areas,
wherein the first metalens, the second metalens and the third metalens overlap one another in the thickness direction of the substrate.

8. The display device of claim 7, wherein:
the first metalens comprises fourth nanostructures having a fourth spacing, a fourth width and a fourth height;
the second metalens comprises fifth nanostructures having a fifth spacing, a fifth width and a fifth height; and
the third metalens comprises sixth nanostructures having a sixth spacing, a sixth width and a sixth height,
wherein the fourth to sixth nanostructures overlap one another in the thickness direction of the substrate.

9. The display device of claim 8, wherein the fourth nanostructures, the fifth nanostructures and the sixth nanostructures have different nanostructures from one another.

10. The display device of claim 3, wherein:
each of the plurality of first light-emitting areas comprises a plurality of first subsidiary light-emitting areas; and
each of the plurality of second light-emitting areas comprises a plurality of second subsidiary light-emitting areas,
wherein the plurality of first subsidiary light-emitting areas are arranged adjacent to each other in a first direction parallel to an upper surface of the substrate,
the plurality of second subsidiary light-emitting areas are arranged adjacent to each other in the first direction, and
the plurality of first subsidiary light-emitting areas and the plurality of second subsidiary light-emitting areas are arranged alternately in a second direction perpendicular to the first direction and parallel to the upper surface of the substrate.

11. The display device of claim 10, wherein the plurality of metalenses comprises:
a first metalens overlapping with one of the plurality of first subsidiary light-emitting areas in the thickness direction of the substrate; and
a second metalens overlapping with one of the plurality of second subsidiary light-emitting areas in the thickness direction of the substrate.

12. The display device of claim 11, wherein at least one first subsidiary emission area or second subsidiary emission area is disposed between the first metalens and the second metalens in the first direction.

13. The display device of claim 12, wherein the first metalens and the second metalens are adjacent to each other in the second direction.

14. The display device of claim 13, wherein a distance between the first metalens and the second metalens adjacent to each other in the first direction is greater than a distance between the first metalens and the second metalens adjacent to each other in the second direction.

15. The display device of claim 1, further comprising:
a color filter layer comprising color filters and a black matrix disposed on the encapsulation layer,
wherein the plurality of metalenses overlap with the color filters in the thickness direction of the substrate.

16. The display device of claim 1, wherein edges of the plurality of metalenses overlap with the pixel-defining layer in the thickness direction of the substrate.

17. The display device of claim 1, further comprising:
a touch sensing layer disposed on the encapsulation layer and comprising touch electrodes,
wherein edges of the plurality of metalenses overlap with edges of the touch electrodes in the thickness direction of the substrate.

18. The display device of claim 1, further comprising:
a touch sensing layer disposed on the encapsulation layer and comprising touch electrodes,
wherein the plurality of metalenses does not overlap with the touch electrodes in the thickness direction of the substrate.

19. The display device of claim 1, further comprising:
a polarizing member disposed on the encapsulation layer.

20. An electronic device including a display device, the display device comprising:
a substrate;
a plurality of light-emitting areas comprising a plurality of light-emitting elements arranged on the substrate;
a pixel-defining layer defining the plurality of light-emitting areas;
an encapsulation layer disposed on the plurality of light-emitting elements and the pixel-defining layer; and
a metalens layer disposed on the encapsulation layer and comprising a plurality of metalenses,
wherein the plurality of metalenses overlaps with some of the plurality of light-emitting areas in a thickness direction of the substrate.
